(19) United States
(12) Patent Application Publication
(10) Pub. No.: US 2015/0107878 A1
(43) Pub. Date: Apr. 23, 2015

(54) INVISIBLE PATTERNS FOR TRANSPARENT ELECTRICALLY CONDUCTIVE FILMS

(71) Applicant: Carestream Health, Inc., Rochester, NY (US)

(72) Inventors: Andrew T. Fried, Woodbury, MN (US); Robert S. Loushin, Eagan, MN (US); Robert J. Monson, Roseville, MN (US)

(21) Appl. No.: 14/501,409

(22) Filed: Sep. 30, 2014

Related U.S. Application Data
(60) Provisional application No. 61/893,387, filed on Oct. 21, 2013.

(51) Int. Cl. H05K 1/02; H05K 3/10; G06F 3/044

(52) U.S. Cl. CPC H05K 1/0296; G06F 3/044; H05K 3/10; H05K 2201/032; H05K 2203/0537
USPC 174/253; 29/846

(57) ABSTRACT

Electrically conductive films and methods for making them. The films include at least two patterns, the first of which, alone, would be visible, but with the addition of one or more other patterns, becomes invisible to the unaided human eye. These films are useful in applications where invisible patterning is desirable, such as, for example, devices employing touch screens.

### CROSS REFERENCE TO RELATED APPLICATIONS

This application claims the benefit of U.S. Provisional Patent Application No. 61/893,387, filed Oct. 21, 2013, entitled “INVISIBLE PATTERNS FOR TRANSPARENT ELECTRICALLY CONDUCTIVE FILMS,” which is hereby incorporated by reference in its entirety.

### BACKGROUND

WO 2013/095971 to Pellerite et al. discloses laser patterning a “valley” into a transparent electrical conductor comprising silver nanowires. U.S. Pat. No. 7,355,283 to Chiu et al. discloses forming a rigid wave pattern design on an electrical connector. U.S. Pat. No. 5,711,877 to Gonzalez discloses a filter element etched with a crosshatch design. U.S. Pat. No. 5,192,240 to Komatsu discloses fabricating a microelectronic device that comprises a step of etching. U.S. Patent Publication No. 2012/0103660 to Gupta et al. discloses forming a transparent conductor comprising a nanostructure layer that may be subjected to patterning. U.S. Pat. No. 5,702,565 discloses laser scribing a pattern in a laminate. U.S. Pat. No. 5,725,787 to Curtin et al. discloses making a light-emitting device that includes a step of etching. U.S. Pat. No. 5,386,221 to Allen et al. discloses apparatuses and methods for generating circuit patterns on a substrate using a laser. U.S. Pat. No. 4,328,410 to Slivinsky et al. discloses a laser skiving system. U.S. Pat. No. 8,409,771 to Ku et al. discloses a laser pattern mask for patterning a substrate. Pothoven, Terry, “Making Displays Work for You: Laser Patterning of Silver Nanowire-The use of laser patterning on silver nanowire enables reduced manufacturing costs and increased flexibility for touch-panel manufacturers,” Information Display 28.9 (2012): 20 discloses the use of laser patterning on silver nanowire. U.S. Patent Publication No. 2011/0248949 to Chang et al. discloses methods and devices related to reducing the effects of differences in parasitic capacitances in touch screens. U.S. Patent Publication No. 2012/0113047 to Hanauer et al. discloses systems and methods for determining multiple touch events in a multi-touch sensor system. U.S. Pat. No. 8,174,667 to Allemand et al. discloses a method of forming a conductive film comprising a plurality of interconnecting nanostructures. WO20111106438 to Dai et al, discloses a method of patterning nanowire-based transparent conductors. U.S. Pat. No. 8,279,194 to Kent et al, discloses electrode configurations for projected capacitive touch screen. U.S. Patent Publication No, 2011/0102361 to Philipp discloses touch screen electrode configurations. U.S. Patent Publication No, 2012/0094090 to Yamazaki et al. discloses a method for forming transparent conductive layer pattern. U.S. Patent Publication No. 2012/0031647 to Hwang et al. discloses a method for manufacturing a conductive pattern. Campbell et al. explains human perception of visual elements, Campbell, F. W. and Robson, J. G. “Application of Fourier Analysis to the Visibility of Gratings.” J. Physiol. (1968), 197, pp. 551-566, U.S. Pat. No. 5,394,483 to Daly discloses a method and apparatus for determining visually perceptible differences between images. U.S. Pat. No. 5,905,819 to Daly discloses a method and apparatus for hiding one image or pattern within another, U.S. Pat. No. 7,483,547 to Hannigan et al. discloses perceptual modeling of media signals for data hiding. U.S. Pat. No. 8,467,105 to Ray discloses optimal contrast level draft-mode printing using spatial frequency analysis. EP 2,479,650 to Klinteberg et al. discloses a product with a coding pattern. U.S. Pat. No. 5,197,765 to Mowry, Jr. et al. discloses a varying tone securing document. U.S. Patent Publication No. 2012/0031647 to Hwang et al. discloses a conductive pattern and manufacturing method thereof.

### SUMMARY

In some embodiments, a device is disclosed as comprising an electrically conductive film comprising a first set of electrically conductive nanostructures in a first region exhibiting a first conductivity and a second set of electrically conductive nanostructures in a second region exhibiting a second conductivity, the second conductivity being greater than the first conductivity, a first pattern disposed in the first region of the electrically conductive film along a first path having a first shape that exhibits a first spatial frequency distribution, and a second pattern disposed in the second region of the electrically conductive film along a second path having a second shape that exhibits a second spatial frequency distribution, where the combination of the first pattern in the first region and the second pattern in the second region result in a combined spatial frequency distribution that is invisible to the unaided human eye.

In some embodiments, the first set of electrically conductive nanostructures has a first average length and the second set of electrically conductive nanostructures has a second average length, the first average length being smaller than the second average length. In some embodiments, the second shape is geometrically similar to the first shape. In some embodiments, the second shape is substantially identical to the first shape.

In some embodiments, the first shape has a maximum contrast at a first spatial frequency, and the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.

In some embodiments, a third pattern is disposed in the second region of the conductive film. In some embodiments, the first and second shapes comprise straight lines. In some embodiments, the first spatial frequency distribution and the second spatial frequency distribution are two-dimensional. In some embodiments, the first path is a continuous path, and the second path is a discrete path. In some embodiments, the electrically conductive nanostructures comprises silver nanowires.

In some embodiments, a method is disclosed as comprising providing an electrically conductive film comprising a first set of electrically conductive nanostructures in a first region exhibiting a first conductivity and a second set of electrically conductive nanostructures in a second region exhibiting a second conductivity, forming a visible first pattern in the first region of the electrically conductive film along a first path having a first shape that exhibits a first spatial frequency distribution, and forming a second pattern in the second region of the electrically conductive film along a second path having a second shape that is geometrically similar to the first shape that forms a second spatial frequency distribution, where, after forming the first pattern in the first region and forming the second pattern in the second region, the first region of the conductive film exhibits a third conductivity that is less than the second conductivity and the combination of the first pattern in the first region and the second pattern in the second region result in a combined spatial frequency distribution that is invisible to the unaided human eye.

In some embodiments, the first set of electrically conductive nanostructures has a first average length and the second set of electrically conductive nanostructures has a second average length, the first average length being smaller than the second average length. In some embodiments, the first spatial frequency distribution and the second frequency distribution are two-dimensional.

In some embodiments, a third pattern is disposed in the second region of the electrically conductive film. In some embodiments, the first shape and second shape each comprise at least one straight line. In some embodiments, the first shape and second shape each comprise at least one curved line. In some embodiments, the first path is a continuous path, and the second path is a discrete path.

In some embodiments, forming the first pattern in the first region comprises irradiating along a first path with a first radiation source, and forming the second pattern in the second region comprises irradiating along a second path with a second radiation source. In some embodiments, the electrically conductive nanostructures comprise silver nanowires.

In some embodiments, forming the first pattern in the first region comprises irradiating along the first path with a first radiation source at a first power, and wherein forming the second pattern in the second region comprises irradiating along the second path with a second radiation source at a second power, the first power being greater than the second power.

In some embodiments, forming the first pattern in the first region comprises irradiating along the first path with a first radiation source at a first repetition rate, and wherein forming the second pattern in the second region comprises irradiating along the second path with a second radiation source at a second repetition rate, the first repetition rate being greater than the second repetition rate.

In some embodiments, forming the first pattern in the first region comprises irradiating along the first path with a first radiation source at a first scan speed, and wherein forming the second pattern in the second region comprises irradiating along the second path with a second radiation source at a second scan speed, the second scan speed being greater than the second scan speed.

In some embodiments, forming the first pattern in the first region comprises irradiating along the first path with a first radiation source at a first pulse-to-pulse overlap percent, and wherein forming the second pattern in the second region comprises irradiating along the second path with a second radiation source at a second pulse-to-pulse overlap percent, the first pulse-to-pulse overlap percent being greater than the second pulse-to-pulse overlap percent.

In some embodiments, the first radiation source and the second radiation source are the same. In some embodiments, the first radiation source and the second radiation source are different. In some embodiments, forming the first pattern in the first region comprises exposing the first region of the electrically conductive film along the first path with an etchant, and wherein forming the second pattern in the second region comprises exposing the second region of the electrically conductive film along the second path with the etchant.

In some embodiments, prior to forming the pattern in the first region and the second pattern in the second region, the first region exhibits a first preexisting set of optical properties and the second region exhibits a second preexisting set of optical properties, and after forming the pattern in the first region and the second pattern in the second region, the first region exhibits a first consequent set of optical properties and the second region exhibits a second consequent set of optical properties, the first consequent set of optical properties and the second consequent set of optical properties being substantially identical.

In some embodiments, the first consequent set of optical properties comprises a first consequent total light transmission and the second consequent set of optical properties comprises a second consequent total light transmission that is substantially identical to the first consequent total light transmission.

In some embodiments, the first consequent set of optical properties comprises a first consequent haze and the second consequent set of optical properties comprises a second consequent haze that is substantially identical to the first consequent haze.

In some embodiments, the first consequent set of optical properties comprises a first consequent L* value and the second consequent set of optical properties comprises a second consequent L* value that is substantially identical to the first consequent L* value.

In some embodiments, the first consequent set of optical properties comprises a first consequent a* value and the second consequent set of optical properties comprises a second consequent a* value that is substantially identical to the first consequent a* value.

In some embodiments, the first consequent set of optical properties comprises a first consequent b* value and the second consequent set of optical properties comprises a second consequent b* value that is substantially identical to the first consequent b* value.

In some embodiments, the first consequent set of optical properties comprises a first consequent distribution of spectral values and the second consequent set of optical properties comprises a second consequent distribution of spectral values that is substantially identical to the first consequent distribution of spectral values.

In some embodiments, the first consequent set of optical properties comprises a first consequent reflectance value and the second consequent set of optical properties comprises a second consequent reflectance value that is substantially identical to the first consequent reflectance value.

In some embodiments, after forming the second pattern in the second region of the electrically conductive film, the second region exhibits a fourth conductivity, the fourth conductivity and the second conductivity being substantially identical.

In some embodiments, the magnitude of the first spatial frequency distribution is composed of spatial frequencies substantially identical to the magnitude of the second spatial frequency distribution.

In some embodiments, the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.

In some embodiments, a system is disclosed as comprising a first electrically conductive film comprising a first set of electrically conductive nanostructures in a first region exhibiting a first conductivity and second set of electrically conductive nanostructures in a second region exhibiting a second conductivity, the first conductivity being greater than the second conductivity, a first pattern disposed in the first region of the first electrically conductive film along a first path having a first shape comprising one or more lines that exhibits a first spatial frequency distribution, a second pattern disposed in the second region of the first electrically conductive film along a second path having a second shape comprising one or more lines that exhibits a second spatial frequency distribution, where the combination of the first pattern in the first region and the second pattern in the second region result in a combined spatial frequency distribution that is invisible to the unaided human eye; where the first electrically conductive film is operable to detect a change in capacitance.

In some embodiments, a second conductive film is disclosed as comprising a third set of electrically conductive nanostructures in a third region exhibiting a third conductivity and fourth set of electrically conductive nanostructures in a fourth region exhibiting a fourth conductivity, the third conductivity being greater than the fourth conductivity, a third pattern disposed in the third region of the second electrically conductive film along a third path having a third shape that exhibits a third spatial frequency distribution, a fourth pattern disposed in the fourth region of the second electrically conductive film along a fourth path having a second shape that exhibits a fourth spatial frequency distribution, where the combination of the first pattern in the first region and the second pattern in the second region result in a combined spatial frequency distribution that is invisible to the unaided human eye; where the first electrically conductive film and second electrically conductive film are operable to detect a change in capacitance.

In some embodiments, a method is disclosed as comprising providing a first electrically conductive film comprising a first set of electrically conductive nanostructures in a first region exhibiting a first conductivity and second set of electrically conductive nanostructures in a second region exhibiting a second conductivity, the first conductivity being greater than the second conductivity, a visible first pattern disposed in the first region of the first electrically conductive film along a first path having a first shape comprising a line that exhibits a first spatial frequency, and modifying the first pattern to form a modified pattern having a modified spatial frequency distribution that is invisible to the unaided human eye.

In some embodiments, modifying the first pattern comprises adding a second pattern, and wherein the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.

In some embodiments, a method is disclosed as comprising adding a second pattern that exhibits a second spatial frequency distribution to a transparent electrically conductive film comprising a visible first pattern that exhibits a first spatial frequency distribution, the visible first pattern comprising a first shape that comprises a boundary that defines a body portion and a plurality of projections extending from the body portion, the second pattern comprising a plurality of spaced apart lines disposed in a region within the plurality of projections of the first shape, where the combination of the first pattern and the second pattern results in a combined spatial frequency distribution that is invisible to the unaided human eye.

In some embodiments, the body portion has a longitudinal dimension, and each of the plurality of projections is substantially perpendicular to the longitudinal dimension of the body portion. In some embodiments, each of the plurality of spaced apart lines of the second pattern is substantially parallel to the longitudinal dimension of the body portion. In some embodiments, areas near the boundary of the first pattern exhibit a first conductivity and the region comprising the second pattern exhibits a second conductivity, the second conductivity being greater than the first conductivity. In some embodiments, the first shape has a maximum contrast at a first spatial frequency, and wherein the first shape of the first pattern is disposed in a first position and the second shape of the second pattern is disposed in a second position that is about 180 degrees out of phase with the first position at the first spatial frequency.

In some embodiments, a method is disclosed as comprising adding a second pattern that exhibits a second spatial frequency distribution to a transparent electrically conductive film comprising a visible first pattern comprising a first shape having a boundary that exhibits a first spatial frequency distribution, the second pattern comprising a plurality of spaced apart shapes disposed in a region near the visible first pattern, where the combination of the first pattern in the first region and the second pattern in the second region result in a combined spatial frequency distribution that is invisible to the unaided human eye.

In some embodiments, the plurality of spaced apart shapes comprises a plurality of spaced apart lines. In some embodiments, the visible first pattern comprises a first shape, the first shape having a boundary defining a body portion having a longitudinal dimension and a plurality of projections extending substantially perpendicular from the longitudinal dimension of the body portion. In some embodiments, each of the plurality of spaced apart shapes of the second pattern is substantially parallel to the longitudinal dimension of the body portion. In some embodiments, areas near the boundary of the first pattern exhibit a first conductivity and the region comprising the second pattern exhibits a second conductivity, the second conductivity being greater than the first conductivity. In some embodiments, the first shape has a maximum contrast at a first spatial frequency, and wherein the first shape of the first pattern is disposed in a first position and the second shape of the second pattern is disposed in a second position that is about 180 degrees out of phase with the first position at the first spatial frequency.

In some embodiments, a method is disclosed as comprising adding a second pattern that exhibits a second spatial frequency distribution to a second region of a transparent electrically conductive film comprising a visible first pattern that exhibits a first spatial frequency distribution, where the combination of the first pattern and the second pattern results in a combined spatial frequency distribution that is invisible to the unaided human eye.

In some embodiments, the first pattern comprises a first shape, the first shape having a boundary defining a body portion having a longitudinal dimension and a plurality of projections extending substantially perpendicular from the longitudinal dimension of the body portion, and wherein the second pattern is disposed within the first shape. In some embodiments, the second pattern comprises a plurality of spaced apart shapes disposed in a region near the first pattern. In some embodiments, the second pattern comprises a plurality of spaced apart rectangles disposed in a region near the first pattern. In some embodiments, the second pattern is disposed in a region within the first pattern. In some embodiments, each of the plurality of spaced apart shapes of the second pattern is disposed substantially parallel to the longitudinal dimension of the body portion.

In some embodiments, the first pattern is disposed in a first region of the transparent electrically conductive film that exhibits a first conductivity, and the second pattern is disposed a second region of the transparent electrically conductive film that exhibits a second conductivity, wherein the second conductivity is greater than the first conductivity. In some embodiments, areas near the boundary of the first pattern exhibit a first conductivity and the region comprising the second pattern exhibits a second conductivity, the second conductivity being greater than the first conductivity.

In some embodiments, the first shape has a maximum contrast at a first spatial frequency, and where the first shape of the first pattern is disposed in a first position and the second shape of the second pattern is disposed in a second position that is about 180 degrees out of phase with the first position at the first spatial frequency. In some embodiments, the second pattern is added by irradiating the transparent electrically conductive film with a UV pulsed laser.

In some embodiments, the first pattern comprises a first shape, the first shape having a boundary defining a body portion having a longitudinal dimension and a plurality of projections extending substantially perpendicular from the longitudinal dimension of the body portion, and where the second pattern is disposed within the first shape substantially perpendicular to the longitudinal dimension of the body portion.

In some embodiments, the first pattern comprises a first shape, the first shape having a boundary defining a body portion having a longitudinal dimension and a plurality of projections extending substantially perpendicular from the longitudinal dimension of the body portion, and wherein the second pattern is disposed within the first shape substantially parallel to the longitudinal dimension of the body portion.

In some embodiments, the first pattern comprises a first shape, the first shape having a boundary defining a body portion having a longitudinal dimension, a plurality of projections extending substantially perpendicular from the longitudinal dimension of the body portion at a first side of the body portion, and a plurality of lines extending from a second side of the body portion opposite the first side and a portion of which extends parallel to the longitudinal dimension of the body portion, further comprising a visible third pattern disposed near the first pattern and comprises a third shape, the third shape having a boundary defining a body portion having a longitudinal dimension, a plurality of projections extending substantially perpendicular from the longitudinal dimension of the body portion at a first side of the body portion, and a plurality of lines extending from a second side of the body portion opposite the first side and a portion of which extends parallel to the longitudinal dimension of the body portion, the plurality of projections of the third shape being aligned with the plurality of projections of the third shape, the plurality of lines of the third shape being substantially parallel with the plurality of lines of the first shape,

further comprising a fourth pattern comprising a plurality of spaced apart lines disposed within the first shape substantially parallel with the longitudinal dimension of the body portion of the first shape, and

where the second pattern is disposed within the first shape substantially parallel with the longitudinal dimension of the body portion of the first shape.

### DESCRIPTION OF FIGURES

FIG. 1A shows a side view of an embodiment of an electrically conductive film.

FIG. 1B shows a perspective view of an embodiment of a patterned electrically conductive film.

FIG. 2 is a graph demarking the range of human contrast perception for an adult human.

FIG. 3A shows an embodiment of an electrically conductive film comprising an unpatterned second region.

FIG. 3B shows a camera image under LED illumination of the electrically conductive film that comprises an unpatterned second region, such as, for example FIG. 3A.

FIG. 3C shows three sets of first patterns comprising a pair of lines in the first region that are interposed by two sets of unpatterned second regions.

FIG. 3D shows a plot of the magnitude of the contrast and the contrast sensitivity as a function of spatial frequency.

FIG. 3E shows a plot of visibility as a function of spatial frequency that is based on FIG. 3D.

FIG. 3F shows a plot of contrast and contrast threshold as function of visibility.

FIG. 4A shows an embodiment of an electrically conductive film comprising a second region patterned with at least one path of discrete lines.

FIG. 4B shows a camera image of the electrically conductive film that comprises a second region patterned with at least one path of discrete lines, such as, for example, FIG. 4A.

FIG. 4C shows three sets of first patterns comprising a pair of lines in the first region that are interposed by two sets of second regions patterned with second patterns of discrete lines.

FIG. 4D shows a plot of the magnitude of the contrast and the contrast sensitivity as a function of spatial frequency.

FIG. 4E shows a plot of visibility as a function of spatial frequency that is based on FIG. 4D.

FIG. 5 shows an embodiment of a backgammon-style pattern on an electrically conductive film.

FIG. 6A shows an embodiment of a computer aided design (CAD) of a sensor comprising a section of a backgammon style pattern, such as that shown in FIG. 5.

FIG. 6B shows an embodiment of a computer aided design (CAD) of a sensor comprising a section of a backgammon style pattern.

FIG. 7A shows a CAD of an electrically conductive film comprising a backgammon style pattern.

FIG. 7B shows a camera image under LED illumination of an electrically conductive film having the pattern, such as that shown in FIG. 7A.

FIG. 8A shows a CAD of an electrically conductive film comprising a backgammon style pattern such as that shown in FIG. 7A with the regions that were unpatterned in FIG. 7A patterned.

FIG. 8B shows a close up of the pattern of FIG. 8A without the first pattern in the first region to show that certain areas of the first region were over-patterned.

FIG. 8C shows a camera image under LED illumination of an electrically conductive film having the pattern, such as that shown in FIGS. 8A and 8B.

FIG. 9A shows a CAD of an electrically conductive film comprising a backgammon style pattern such as that shown in FIG. 8B except that a portion of the lines that were visible was not included.

FIG. 9B shows a camera image of a pattern such as that shown in FIG. 9A.

FIG. 10A is a schematic of a bars and stripes pattern with discrete lines.

FIG. 10B is a schematic of a bars and stripes pattern with open shapes.

FIG. 11A is a schematic of a diamond pattern.

FIG. 11B shows a single diamond comprising discrete lines patterned in both directions, parallel to a first pair of parallel sides and a second pair of parallel sides.

### DESCRIPTION

All publications, patents, and patent documents referred to in this document are incorporated by reference herein in their entirety, as though individually incorporated by reference.

U.S. Provisional Patent Application No. 61/893,387, filed Oct. 21, 2013, entitled “INVISIBLE PATTERNS FOR TRANSPARENT ELECTRICALLY CONDUCTIVE FILMS,” is hereby incorporated by reference in its entirety.

An electrically conductive film may be patterned using a laser to form electrically isolated regions of lower conductivity near regions of higher conductivity. Such electrically conductive films may comprise at least one pattern in a first region and at least one pattern in a second region, the first region exhibiting a lower conductivity than the second region. The patterns in the first region and the second region may be geometrically similar. The use of patterns in multiple regions of different conductivity may render the patterns invisible or of low visibility to the unaided human eye.

### Electrically Conductive Film

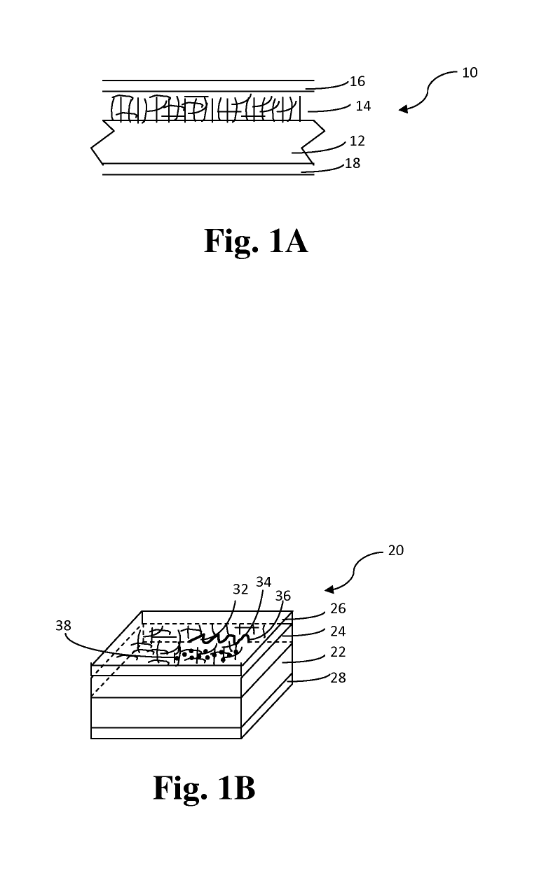

FIG. 1A shows a side view of an embodiment of an electrically conductive film 10. The electrically conductive film 10 may comprise a top coat layer 16, a first electrically conductive layer 14, and a substrate 12, and an optional hard coat layer 18. The top coat layer may be disposed on the electrically conductive layer 14. The electrically conductive layer 14 may be disposed on the substrate 12. In embodiments where the electrically conductive film 10 comprises a hard coat layer 18, the substrate 12 may be disposed on the hard coat layer 18. In some embodiments, the hard coat layer 18 may be replaced by a second electrically conductive layer and a bottom coat layer. In some embodiments, the first electrically conductive layer and the second electrically conductive layer may have the same composition. In some embodiments, the top coat layer and the bottom coat layer may have the same composition. In some embodiments, a primer layer (not shown) may be used to bond the optional hard coat layer 18 to the substrate 12 or the first electrically conductive layer 14 to the substrate 12 or the second electrically conductive layer to the substrate 12. The electrically conductive layer 14 may comprise a plurality of electrical conductors, such as silver nanowires. The plurality of electrical conductors may comprise nanostructures, which may be any structure, groups of structures, particulate molecule, or groups of particulate molecules of potentially varied geometric shape with the shortest dimension sized between 1 nm and 100 nm. In some embodiments, the nanostructures may be metal nanostructures, such as, for example, metal meshes or metal nanowires, including silver nanowires, copper nanowires, or gold nanowires. Other non-limiting examples of nanostructures include carbon nanotubes, transparent conductive oxide, such as indium tin oxide (ITO), and graphene. Silver nanowires are preferred in some embodiments, because of the high electrical conductivity of silver, and the ability of such nanowires to enable simultaneously high optical transparency and high electrical conductivity of the electrically conductive film.

FIG. 1B shows a perspective view of an embodiment of a patterned electrically conductive film 20. The patterned electrically conductive film 20 may be a multi-layer structure that comprises a top coat layer 26, an electrically conductive layer 24, a substrate 22, and an optional hard coat layer 28. The top coat layer 26 may be disposed on the electrically conductive layer 24. The electrically conductive layer 24 may be disposed on the substrate 22. In embodiments where the electrically conductive film 20 comprises a hard coat layer 28, the substrate 22 may be disposed on the hard coat layer 28. In some embodiments, the hard coat layer 28 may be replaced by a second electrically conductive layer and a bottom coat layer. In some embodiments, the first electrically conductive layer and the second electrically conductive layer may have the same composition. In some embodiments, the top coat layer and the bottom coat layer may have the same composition. In some embodiments, a primer layer (not shown) may be used to bond the hard coat layer 28 to the substrate 22 or the electrically conductive layer 24 to the substrate 22 or the second electrically conductive layer to the substrate 22.

The electrically conductive layer 24 may comprise a plurality of electrical conductors, such as silver nanowires. The plurality of electrical conductors may comprise nanostructures, which may be any structure, groups of structures, particulate molecule, or groups of particulate molecules of potentially varied geometric shape with the shortest dimension sized between 1 nm and 100 nm. In some embodiments, the nanostructures may be metal nanostructures, such as, for example, metal meshes or metal nanowires, including silver nanowires. Other non-limiting examples of nano structures include carbon nanotubes, transparent conductive oxide, and graphene. The electrical conductors may be electrically interconnected to impart conductivity to the electrically conductive layer 24 or the electrically conductive film 20 as a multi-layer structure comprising the electrically conductive layer 24. The electrically conductive film 20 may comprise a first region 32 exhibiting a first conductivity and a second region 34 exhibiting a second conductivity. A region may be defined as an area on the surface of the electrically conductive film 20 that may extend into the layers of the electrically conductive film 20 substantially normal to the surface of the electrically conductive film 20 or the top coat layer 26. For example, a region as an area on the surface of the electrically conductive film 20 may extend into the layers of the electrically conductive film 20 substantially normal to the surface of the electrically conductive film 20 when the area is within 10 degrees of a vector normal to the surface of the electrically conductive film 20 or the top coat layer 26. The first region 32 may comprise a first pattern 36. The second region 34 may comprise a second pattern 38. The first region 32 may have a lower conductivity than the second region 34. In some cases, the first region 32 may have no conductivity. The first region 32 may comprise a combination of conducting and non-conducting areas. In such cases, one or more non-conducting areas may be located between a first conducting area and a second conducting area. In some cases, none of the conducting areas connect with each other. In some cases, substantially none of the conducting areas connect with each other, such that the first region 32 maintains a lower conductivity than the second region 34. The combination of the first pattern 36 and the second pattern 38 in the electrically conductive film 20 may be invisible or of low visibility to the unaided human eye.

### Invisible Patterns

An electrically conductive film may comprise a plurality of patterns each of which may be located in different regions of the film. Such patterns may affect the conductivity of the different regions, producing regions of higher conductivity near regions of lower conductivity. The plurality of patterns each of which may be in different regions may render the patterns undetectable to the unaided human eye. Additional patterns may reduce overall or combined pattern visibility outside the contrast sensitivity or visual threshold of the unaided human eye. The contrast sensitivity threshold is the lowest contrast at which a pattern can be seen. Contrast sensitivity threshold of the unaided human eye is discussed in Campbell et al, “Application of Fourier Analysis to the Visibility of Gratings” J. Physiol. (1968), 197, pp. 551-566, which is hereby incorporated by reference herein. In some embodiments, the designs of the patterns in different regions may be substantially similar.

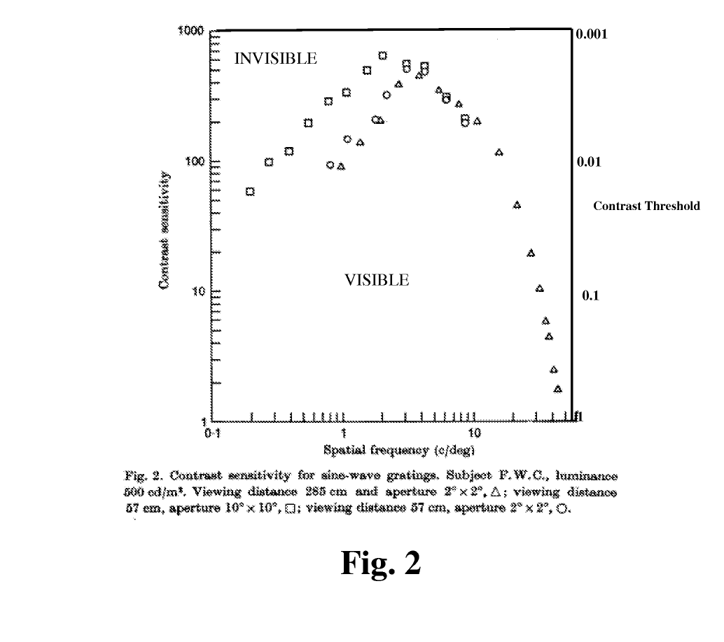

Contrast sensitivity refers to the performance of the unaided human eye and brain system when interpreting an image. Contrast sensitivity is the visual ability to see objects that may not be outlined clearly or that do not stand out from their background. Contrast sensitivity takes into account two variables when viewing an image—the feature size or spatial frequency and contrast of the image. A contrast sensitivity function (CSF) tells us how sensitive we are to various spatial frequencies of visual stimuli. The ability to detect features of different sizes at lower contrasts is expressed as a CSF. The CSF determines the contrast sensitivity threshold. Typically, the unaided human eye can detect medium-sized features when their contrast is low. Smaller features can be detected when their contrast is higher than medium sized features. Larger features also require higher contrast to be visible, which suggests that the human brain may be relatively insensitive to low spatial frequencies. The higher the contrast sensitivity, the lower the contrast level at which an object can be seen. FIG. 2 is a graph demarking the range of human contrast perception for an adult human. As shown, the graph is a plot of threshold contrast and contrast sensitivity, which is 1/threshold contrast, versus spatial frequency (cycles/deg). The area below the curve represents regions where human perception of contrast is strong. The area near or above the curve represents regions where human perception of contrast falls off and becomes invisible.

An electrically conductive film may comprise a first region and a second region, where a first pattern is disposed in the first region, such that the first region exhibits a lower conductivity than the second region. Such a first pattern may be visible to the unaided human eye. In such cases, the first pattern in the first region may be modified to render the first pattern invisible to the unaided human eye. Such modification may include adding a second pattern near the first pattern, such as a second region, to render the first pattern as well as the second pattern invisible to the unaided human eye in a manner such that the first region still maintains a lower conductivity than the second region. The addition of a second pattern may render both the first pattern and the second pattern invisible to the unaided human eye if the combined spatial frequency distribution of the first pattern and the second pattern is outside the range of spatial frequencies visible to the unaided human eye. In some cases, the spatial frequency distribution of either the first pattern or the second pattern may be selected for a combined spatial frequency distribution that does not fall within the resolution of the unaided human eye. In some cases, a first pattern may have a shape that is defined by some boundary enclosing an amount of space that falls within the resolution of the unaided human eye. The effects of the boundary and the empty space within the boundary may contribute at least one component that is visible to the unaided human eye. Such a visible component may be a low frequency spatial component. To mitigate the effects of such visible components, lines may be added to the empty space to mitigate the low spatial frequency or visible components.

In some cases, the orientation or position of the second pattern relative to the first pattern may be selected to obtain a combined spatial frequency distribution above the CSF curve. In some cases, the concentration or density of second pattern(s) or lines of a second pattern in a particular region may be selected to obtain the desired combined spatial frequency distribution. In some cases, the distance between the shapes of the second pattern(s) or between the first pattern and the second pattern may be selected to obtain the desired combined spatial frequency distribution and/or contrast. In some cases, a phase difference between the first pattern and the second pattern may alter the combined spatial frequency. For example, the phase difference may be between about 1 degree and 360 degrees, such as 180 degrees. At medium spatial frequencies where CSF is at or near a maximum, it may be desirable for the second pattern to be about 180 degrees out of phase relative to the first pattern in order to cancel the contrast at this spatial frequency caused by the first pattern. In some cases, the pattern will have visible components in more than direction, such as X and Y. Thus, the positioning of the second pattern relative to the first pattern must be chosen so that contrast cancellation at visible spatial frequencies occurs across the entire pattern in both directions.

In some cases, the visibility of the first pattern on the film prior to the addition of the second pattern is greater than the visibility of the first pattern on the film after the addition of the second pattern. The second region may comprise a minimal number of patterns that would render the first pattern and the minimal number of patterns invisible to the unaided human eye. In some embodiments, the second region comprises a plurality of patterns, such as a third pattern, a fourth pattern, a fifth pattern, a sixth pattern, a seventh pattern, an eighth pattern, a ninth pattern, a tenth pattern, etc.

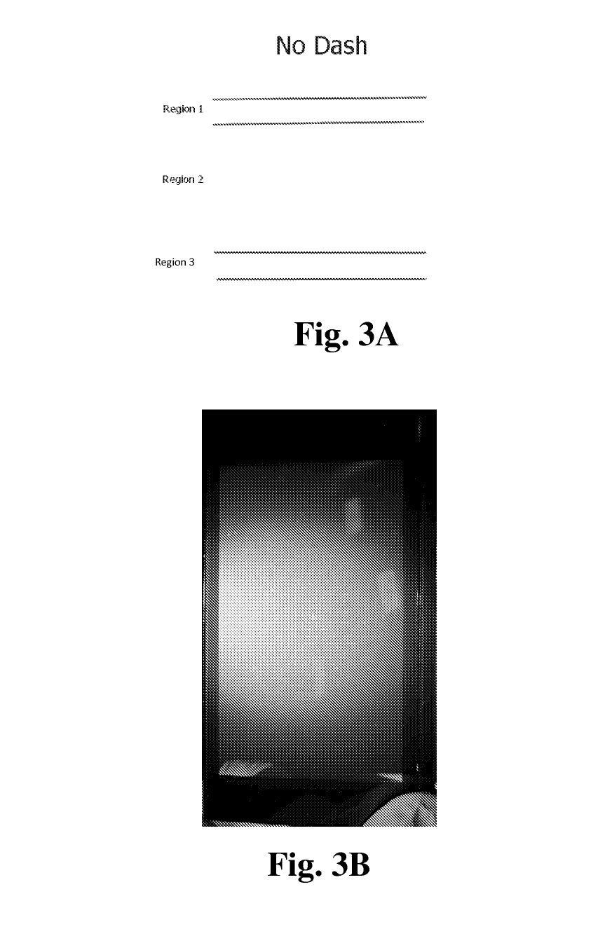

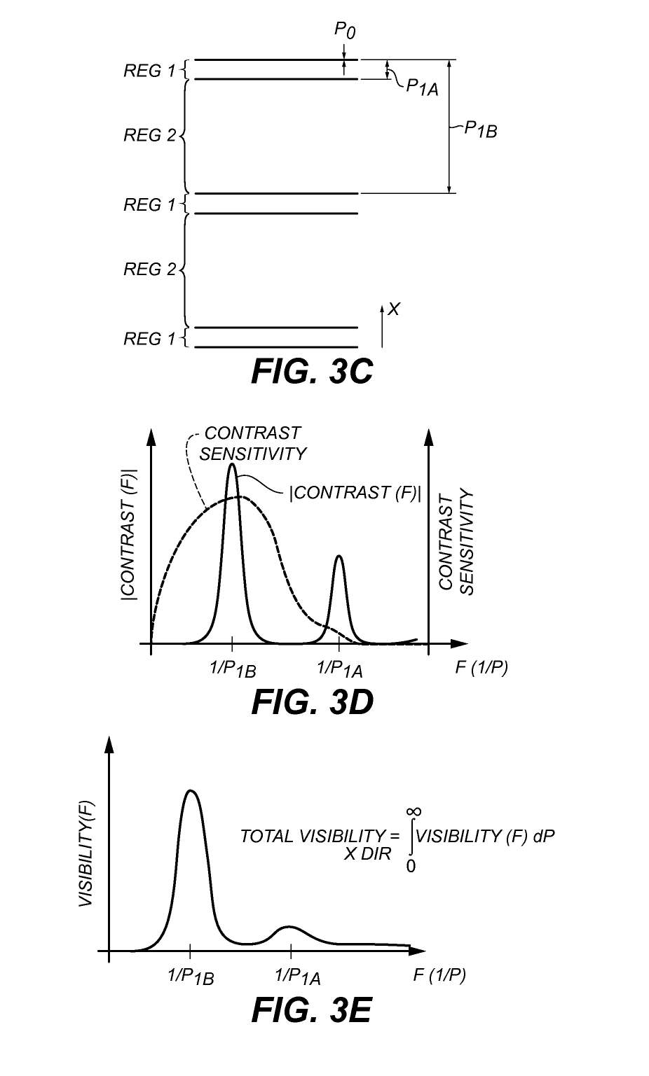

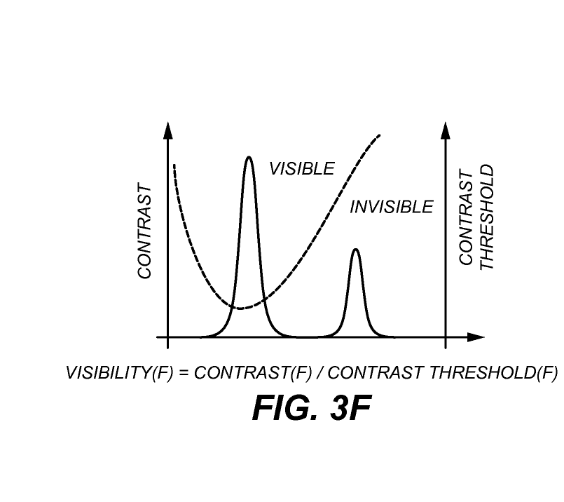

FIGS. 3A-3E relate to an electrically conductive film comprising an unpatterned second region. An electrically conductive film may comprise a first region, a second region, and a third region. As shown, the first region and the third region may each comprise a first pattern comprising two continuous paths. The second region may be positioned between the first region and the third region. The second region may be unpatterned. FIG. 3B shows a camera image under LED illumination of the electrically conductive film that comprises an unpatterned second region, such as that shown in FIG. 3A. Horizontal lines appear visible on the electrically conductive film as light regions interposed with dark regions.

FIG. 3C shows three sets of first patterns comprising a pair of lines in the first region that are interposed by two sets of unpatterned second regions. FIG. 3D shows a plot of the magnitude of the contrast and the contrast sensitivity as a function of spatial frequency. As shown, the solid line shows two curves. The first curve reflects the period between the first pattern of the first region and the subsequent first pattern of the subsequent first region. The second curve reflects the period between the lines of the first pattern. The first curve is at a lower spatial frequency than the second curve. This suggests there is a low frequency component between patterned regions separated by a distance of unpatterned region. There also appears to be higher contrast when viewing the sets of first patterns based on their distance of separation. There appears to be lower contrast when viewing the lines of the first pattern that have less separation distance. FIG. 3E shows a plot of visibility as a function of spatial frequency that is based on FIG. 3D, which shows a first plot in solid lines and a second plot in dotted lines. The first plot is multiplied by the second plot to arrive at the plot of FIG. 3E. As shown, the magnitude of the first peak appears greater than the second peak, which suggests that the majority of the visibility of this pattern is due to the low frequency component caused by the absence of pattern in the second region. The first peak reflects higher visibility between patterned regions separated by the unpatterned region, and the second peak reflects lower visibility in distinguishing the lines of the first pattern. FIG. 3F shows a plot of contrast and contrast threshold as function of visibility. The dotted line reflects the contrast sensitivity perception for the unaided adult human eye. The first curve, which reflects the period of the first pattern of the first region to another first pattern of another first region, extends into the visible region while the second curve, which reflects the period of the lines in one of the first patterns, is in the invisible region. This suggests that the unpatterned region may contribute to the visibility of the first pattern to the unaided human eye.

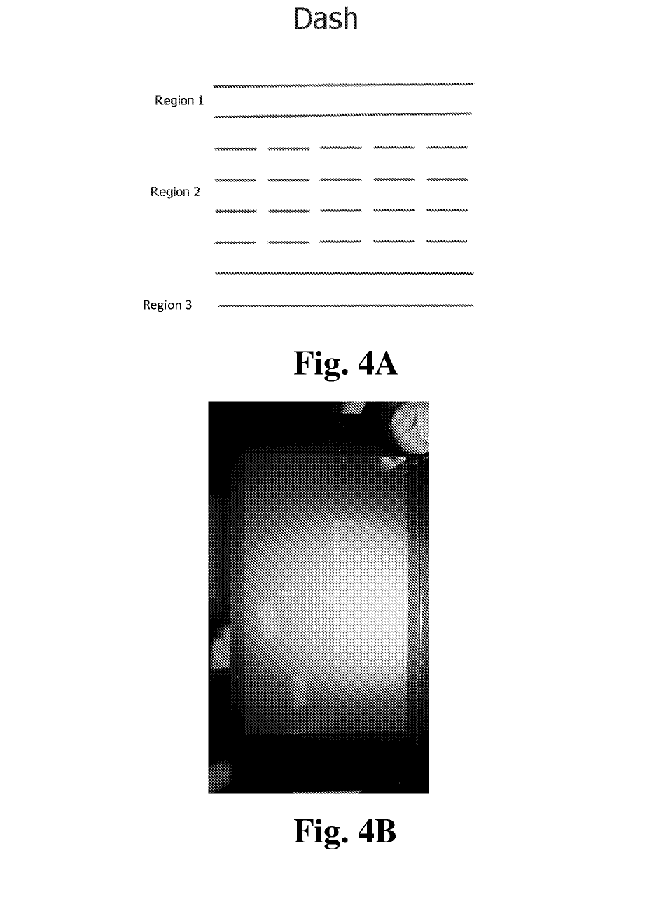

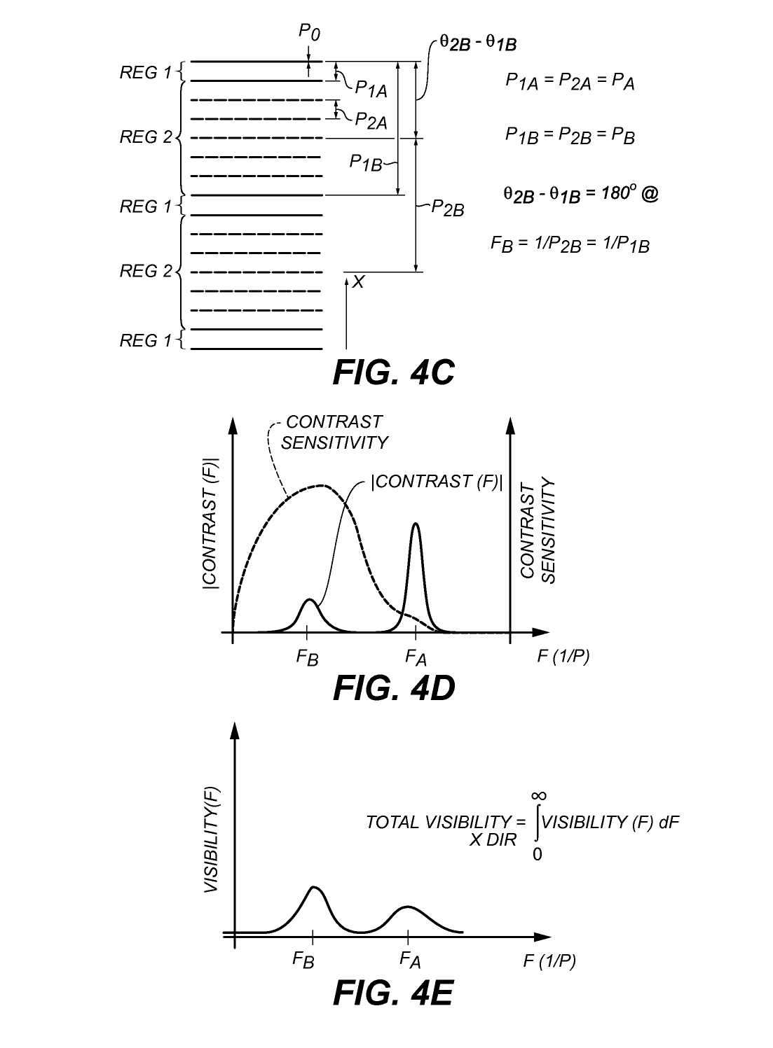

FIGS. 4A-4E relate to an embodiment of an electrically conductive film comprising a second region patterned with at least one path of discrete lines. An electrically conductive film may comprise a first pattern in a first region, a second pattern in a second region, and a third pattern in a third region. The first pattern may cause the first region to exhibit a first conductivity. The second pattern may cause the second region to exhibit a second conductivity. The third pattern may cause the third region to exhibit a third conductivity. In some embodiments, the second conductivity is higher than the first conductivity or the third conductivity. FIG. 4B shows a camera image under the same LED illumination of the electrically conductive film of that comprises a second region patterned with at least one path of discrete lines, such as that shown in FIG. 4A. Horizontal lines appear less visible on the electrically conductive film with mostly light regions. Any dark regions that may be interposed between light regions are barely visible to the unaided human eye.

FIG. 4C shows three sets of first patterns comprising a pair of lines in the first region that are interposed by two sets of second regions patterned with second patterns of discrete lines. The discrete lines of the second patterns are offset in phase by about 180 degrees from the pair of lines of the first patterns. Without wishing to be bound by theory, it is believed that the contrast and/or spatial frequency effects from the offset second patterns may cancel the contrast and/or spatial frequency effects of the first patterns. FIG. 4D shows a plot of the magnitude of the contrast and the contrast sensitivity as a function of spatial frequency. As shown, the solid line shows two curves. The first curve reflects the period between the first pattern of the first region and the subsequent first pattern of the subsequent first region, which are not interposed by a second pattern of discrete lines in a second region. Compared to FIG. 3D, the first curve has a lesser magnitude of the contrast at the lower frequency. Referring to FIG. 3F, the first curve would be pushed into the invisibility region. FIG. 4E shows a plot of visibility as a function of spatial frequency that is based on FIG. 4D, which shows a first plot in solid lines and a second plot in dotted lines. The first plot is multiplied with the second plot to arrive at the plot of FIG. 4E. As shown, the magnitude of the first peak is reduced as compared to the magnitude of the first peak in FIGS. 3A-3F. The contrast between the patterned and unpatterned region is less as well as the visibility. The unaided human eye is less able to recognize the pattern.

Comparing FIG. 3B with FIG. 4B, the pattern of lines in FIG. 3B appears more visible than in FIG. 4B. The electrically conductive films in FIGS. 3B and 4B may be viewed with a camera in a dark room with a dark background and a directionally focused from a small light source, such as an incandescent or LED light bulb. Such a light source may be a Bright Star Razor LED flashlight. Such a camera may be a Samsung MV900F camera. The first and second regions of many typical patterns may repeat with spatial frequencies on the order of 1 to 3 mm, which is near the peak of the contrast sensitivity threshold when the pattern is viewed from an approximate distance of 25 cm. In such cases, the unaided human eye may be able to view the pattern. This may be due to optical parameters, such as haze. Adding patterns to the second region may change the lowest spatial frequency of the combined first and second regions, such that patterns in the first region and/or third region as well as the second region are rendered invisible or less visible to the unaided human eye. Without wishing to be bound by theory, it is believed that by adding patterns to the second region so that the contrast sensitivity function on a large area, such as, for example, a capacitive touch screen having a plurality of regions comprising the patterns of the first region and the second region, may be shifted into a domain that may be primarily higher spatial frequency and possibly lower contrast at the original spatial frequency, thereby making it invisible to the unaided human eye. In some cases, adding high frequency patterns may cancel mid-frequency patterns. In some cases, the second pattern may contain both high and mid-frequency patterns, and the mid-frequency visibility of the first pattern may be cancelled by mid-frequency repetitions of the second pattern out of phase with the mid-frequency of the first pattern.

The first region may comprise a first pattern that may comprise one or more paths (e.g. first path, second path). In some embodiments, each of the paths of the first region may be continuous. As shown in FIG. 4A, the first region may comprise two continuous lines. The second region may comprise a second pattern that may comprise one or more paths (e.g. first path, second path, third path, fourth path, etc.). In some embodiments, each of the paths of the second region may be discrete. As shown in FIG. 4A, the second region may comprise four discrete lines. In some embodiments, the electrically conductive film may comprise a third region. The third region may comprise a third pattern that may comprise one or more paths (e.g. first path, second path). In some embodiments, each of the paths of the third region may be continuous. As shown in FIG. 4A, the third region may comprise two continuous lines. For the purposes of this application, a path may be continuous if it extends without a break or irregularity, and a path may be discrete if they comprise spaced apart lines. In the case of a pulsed laser, a continuous path means that the laser pulses overlap, a discrete path means that the laser pulses do not overlap. A discrete path may comprise pulses that overlap for a first distances, pulses that do not overlap for a second distance, pulses that overlap for a third distance, and so on and so forth. For example, a discrete path may comprise a first line comprising overlapping pulses and a second line comprising overlapping pulses, but the first line and the second line are spaced apart with no pulses overlapping to connect the first line and the second line.

Patterning discrete lines in the second region may render all patterns in the electrically conductive film invisible. Patterning discrete lines in the second region may maintain the second conductivity of the second region to be higher than the first conductivity and/or third conductivity. In some embodiments, patterning discrete lines in the second region minimally affects, if at all, the second conductivity of the second region. Without wishing to be bound by theory, it is believed that electrons may flow between spaced apart lines to maintain the second conductivity to be above the first conductivity and/or third conductivity. In some embodiments, the shape of a path of a pattern may comprise a line, either continuous or discrete. Such lines may be straight or bent. A bend in a line may comprise a curve (or, in other words, a wave) or a sharp angle. For the purposes of this application, a straight line has no curvature. For the purposes of this application, a curve has almost everywhere a non-zero curvature, and a curvature is the amount by which a geometric object deviates from being flat or straight, such as a straight line. Mathematically, a curve may be characterized as having continuous first derivatives and second derivatives that are almost everywhere non-zero. In some cases, a curve may be a line that comprises a wave. In some cases, a curve may lack angles or sharp corners (i.e., it possesses finite curvature along its length). In some cases, the bend in a line may be smooth or rounded or sharp. The bends in a line may be periodic or aperiodic. In some embodiments, the shape of a path of a pattern may comprise open or close geometric shapes, such as polygons, circles, rectangles, triangles, or the like. Such shapes may be symmetric or non-symmetric. In some embodiments, the pattern may comprise a plurality of open or closed, symmetric or non-symmetric geometric shapes or a plurality of straight or curved lines.

In some embodiments, the shape of the path(s) of the first pattern in the first region may be geometrically similar to the shape of the path(s) of the second pattern in the second region, but the path(s) of the first pattern may be continuous and the path(s) of the second pattern may be discrete. In some embodiments, the shape of the path(s) of the third pattern in the third region may be geometrically similar to the shape of the path(s) of the second pattern in the second region, but the path(s) of the third pattern may be continuous and the path(s) of the second pattern may be discrete. In some embodiments, the first pattern and the third pattern are substantially identically. For the purposes of this application, “substantially identical” means differences that are not discernible by the unaided human eye.

In some embodiments, the shape of the first paths of the first pattern, the second pattern, and the third pattern may each comprise a straight line. In some embodiments, the shape of the first paths of the first pattern, the second pattern, and the third pattern may each comprise a curved line. In some embodiments, the shape of the first paths of the first pattern, the second pattern, and the third pattern may each comprise a waveform. Waveforms may comprise sine, square, triangle, saw tooth waveforms, or a sum of multiple waveforms at multiple spatial frequencies. In some embodiments, the first pattern may comprise a plurality of paths. In some embodiments, the second pattern may comprise a plurality of paths. In such cases, each of the plurality of paths may form a geometric shape, such as a square. In such cases, the squares in the second pattern may comprise discrete lines, such that the squares are open shapes, and the squares in the first pattern may be comprise continuous lines, such that the squares are closed shapes.

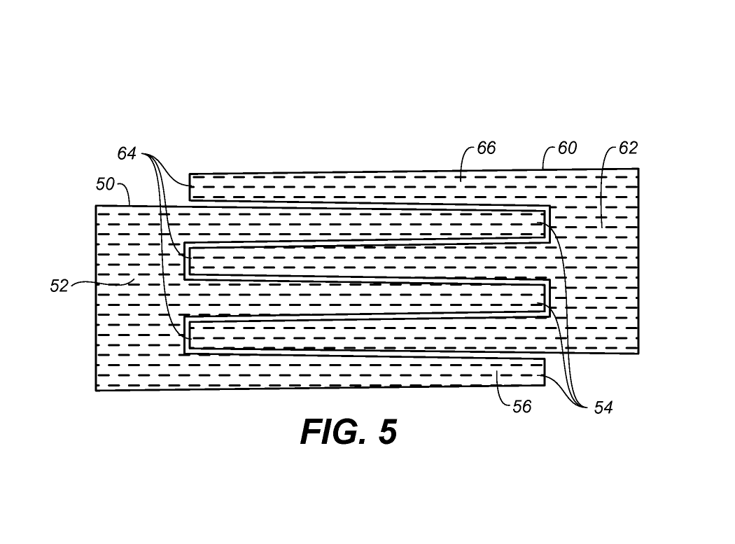

FIG. 5 shows an embodiment of a backgammon-style pattern. Such patterns may be formed on electrically conductive films to form regions of differing conductivities. The backgammon-style pattern may comprise a first pattern 50 and/or a third pattern 60. The first pattern 50 and the third pattern 60 may be disposed on the same electrically conductive film or on separate electrically conductive films, such that the first pattern 50 is in a different layer from the third pattern 60. The first pattern 50 may form a shape that comprises a body portion 52 and a plurality of projections 54 extending from the body portion 52. The projections 54 are substantially perpendicular to the body portion 52. The third pattern 60 may form a similar, if not substantially identical shape to the first pattern 50. The third pattern 60 may form a shape that comprises a body portion 62 and a plurality of projections 64 extending from the body portion 62. The projections 64 are substantially perpendicular to the body portion 62. Whether disposed on the same or in different layers, the first pattern 50 and the third pattern 60 are positioned and oriented relative to one another, such that the first pattern 50 and the third pattern 60 are interdigitated. The spacing between projections 54 and 64 where they interdigitate may in some cases be about 20 microns.

The first pattern 50 and/or third pattern 60 may be visible along the interdigitation regions between the projections 54 of the first pattern 50 and the projections 64 of the third pattern 60. Without wishing to be bound by theory, it is believed that the concentrated density of parallel lines near the interdigitation regions affords a lower spatial frequency and high contrast that is visible to the unaided human eye. To correct for this phenomena, a second pattern comprising discrete or dashed lines 56, 66 may be added to the interior areas within the boundaries of the shapes formed by the respective patterns. The second pattern may be parallel to the lines forming the projections 54, 64. The discrete lines 56, 66 may cancel out the low spatial frequency of the lines in the interdigitation regions.

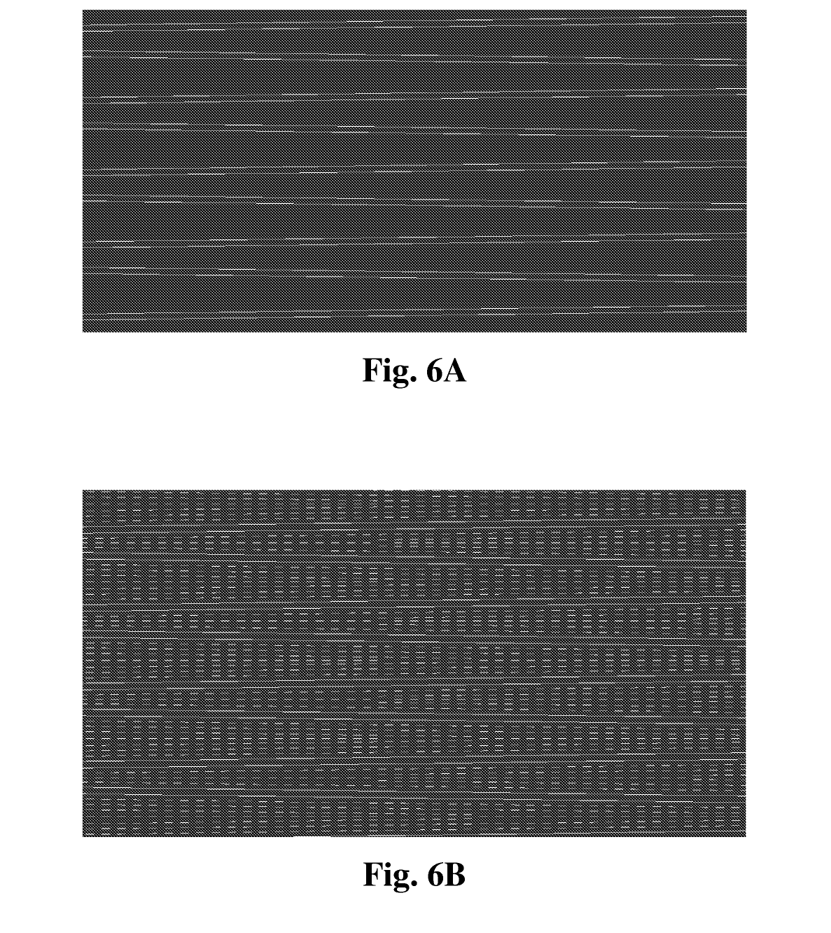

FIG. 6A shows an embodiment of a computer aided design (CAD) of a sensor comprising a section of a backgammon style pattern, such as that shown in FIG. 5. As shown, the sensor comprises a plurality of first regions and second regions. The second regions are unpatterned. FIG. 6B shows an embodiment of a computer aided design (CAD) of a sensor comprising a section of a backgammon style pattern. As shown, the sensor comprises a plurality of first regions and second regions. Each of the second regions comprises a second pattern that comprises at least one path of discrete lines. The embodiment of FIG. 6B results in a reduction in visibility of the pattern similar to the result illustrated in FIG. 4B as compared to FIG. 3B.

Prior to providing the first pattern, the first region may exhibit a first preexisting conductivity. After providing the first pattern, the first region may exhibit a first consequent conductivity. Prior to providing the second pattern, the second region may exhibit a second preexisting conductivity. After providing the second pattern, the second region may exhibit a consequent conductivity. In some embodiments, the second region may exhibit a second consequent conductivity that is substantially identical to the second preexisting conductivity. In some cases, the difference between the second preexisting conductivity and the second consequent conductivity of the second region may be within 10% of each other. In some embodiments, the second consequent conductivity may be less than the second preexisting conductivity but higher than the first preexisting conductivity or first consequent conductivity.

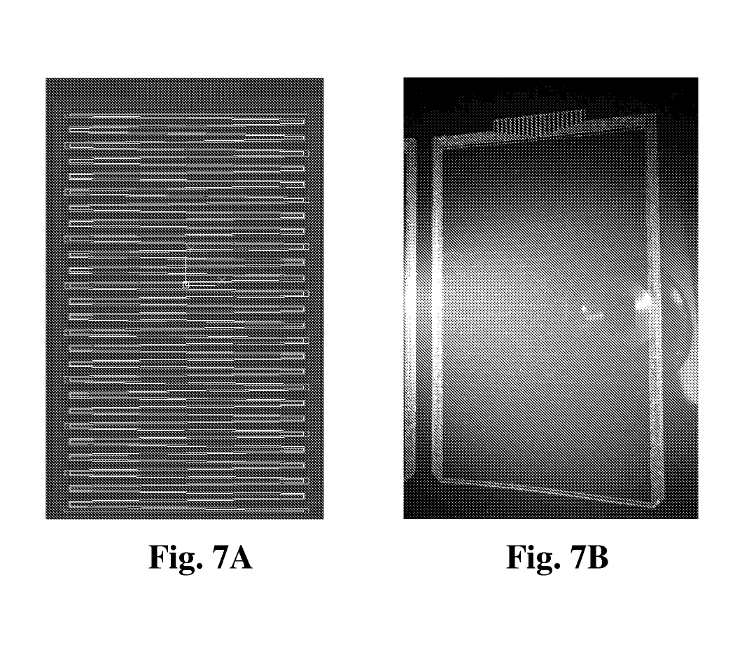

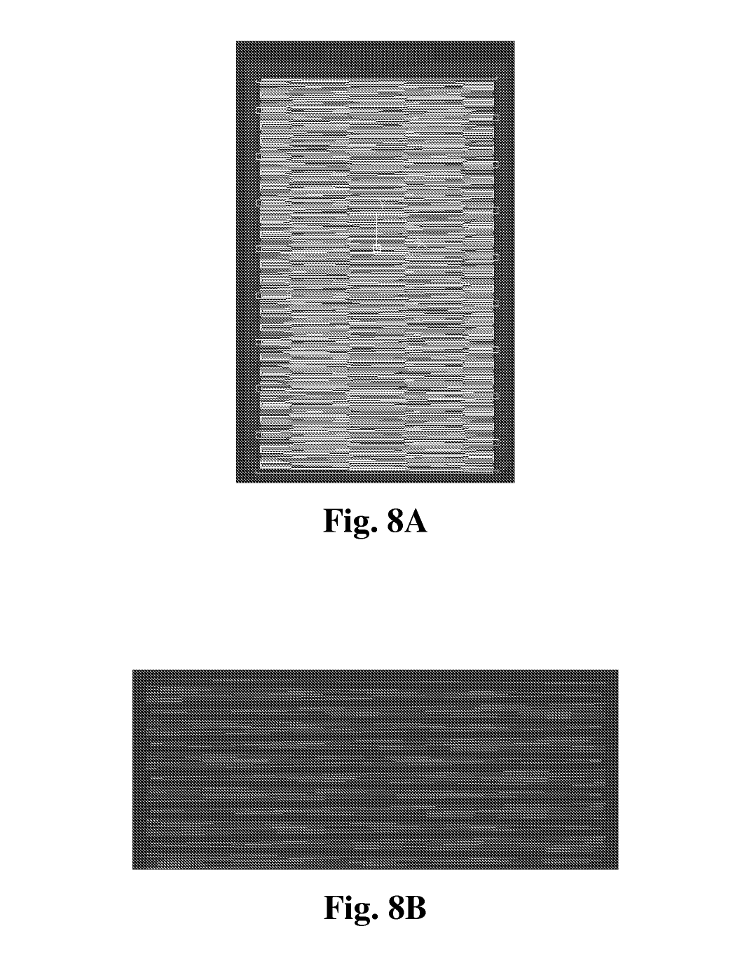

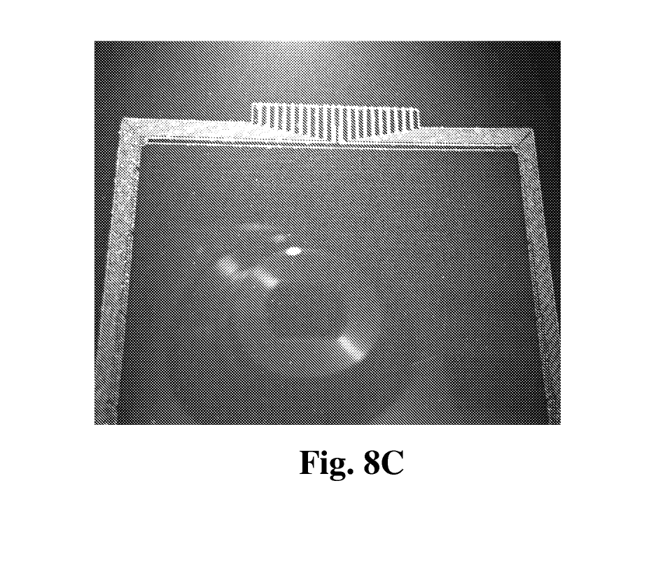

FIG. 7A shows a CAD of an electrically conductive film comprising a backgammon style pattern. As shown, the pattern comprises several lines that form a plurality of first regions and second regions. The second regions are unpatterned. FIG. 7B shows a camera image under LED illumination of an electrically conductive film having the pattern, such as that shown in FIG. 7A. As shown, horizontal lines across the electrically conductive film are visible. FIG. 8A shows a CAD of an electrically conductive film comprising a backgammon style pattern such as that shown in FIG. 7A with the regions that were unpatterned in FIG. 7A patterned. As shown, the electrically conductive film appears to be substantially patterned with lines. FIG. 8B shows a close up of the pattern of FIG. 8A without the first pattern in the first region to show that certain areas of the first region were over-patterned. As shown in FIG. 8B, there appears to be a concentrated patterned area. FIG. 8C shows a camera image under LED illumination of an electrically conductive film having the pattern such as that shown in FIGS. 8A and 8B. As shown, a smaller segment of the horizontal lines in FIG. 7B is visible near the concentrated patterned area as shown in FIG. 8B as opposed to the horizontal lines that were substantially visible along the length of the touch screen as shown in FIG. 7B. FIG. 9A shows a CAD of an electrically conductive film comprising a backgammon style pattern such as that shown in FIG. 8B except that a portion of the lines that were visible were not included. FIG. 9B shows a camera image of a pattern such as that shown in FIG. 9A. As shown, the pattern is invisible to the unaided human eye.

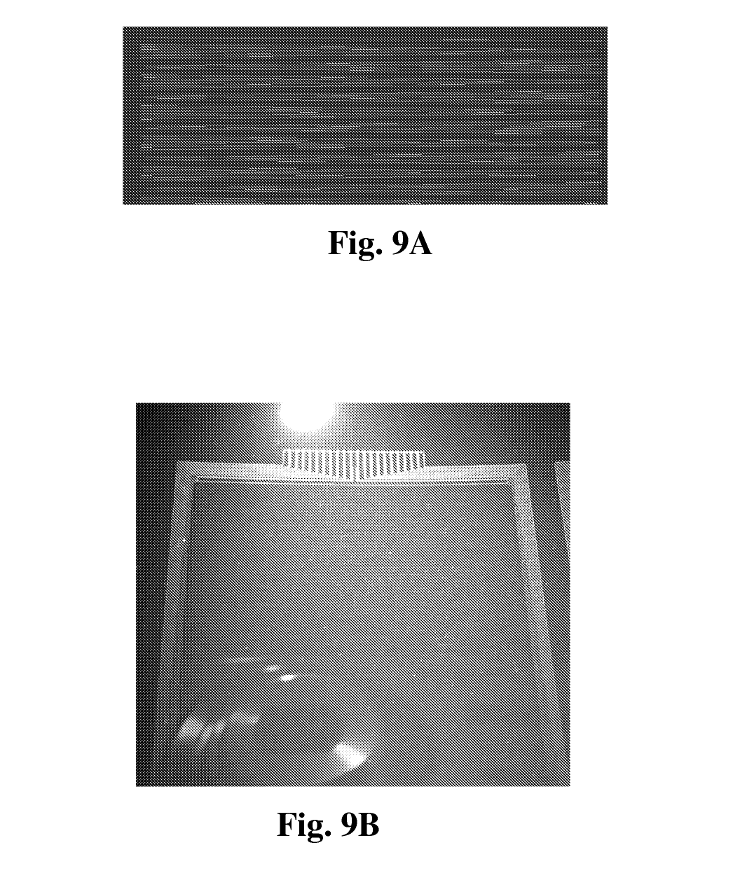

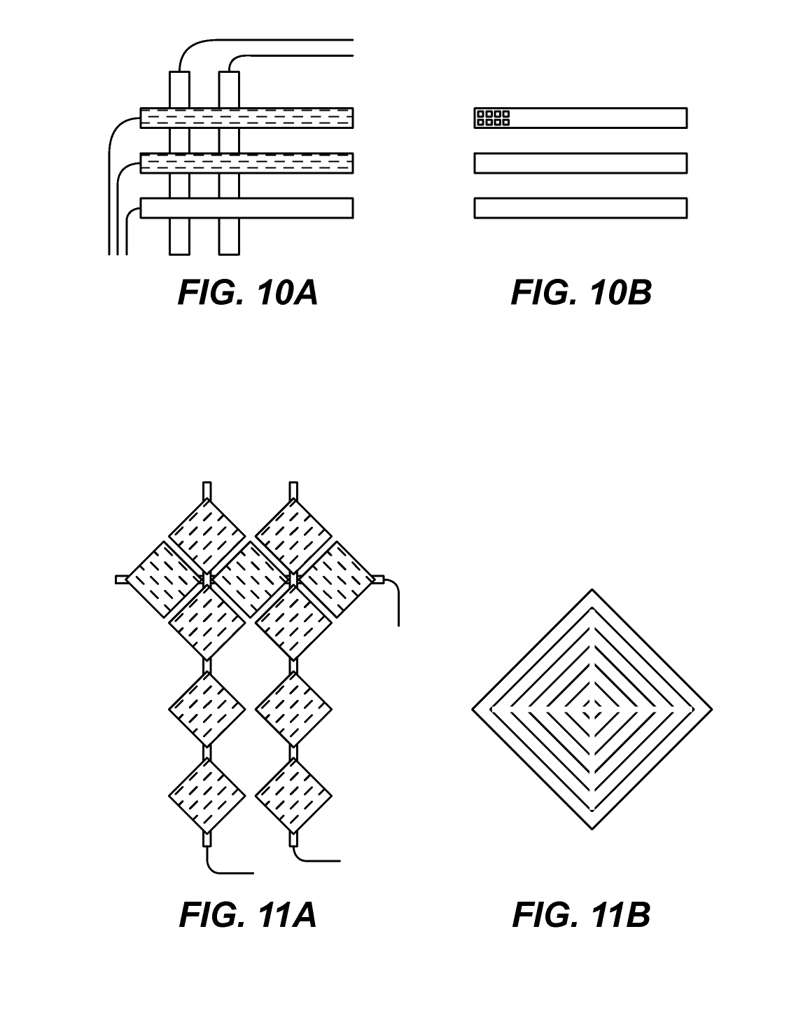

FIG. 10A is a schematic of a bars and stripes pattern with discrete lines. The horizontal bars and the vertical stripes may be in the same or separate layers. The spacing between horizontal bars may in some cases be about 20 microns. In some embodiments, dashed lines may be positioned within the horizontal bars and/or vertical stripes parallel to their longitudinal dimensions. It is believed that such placement may render the lines of the bars and strips pattern invisible. FIG. 10B is a schematic of a bars and stripes pattern with open shapes. As shown, the open shapes are rectangles, such as squares. The shapes for making a pattern invisible may be the same shape as the shape of the pattern. For example, the bars are in the shape of the rectangle, and the second patterns may be in the shape of a rectangle although the rectangle may be open with discrete lines delineating the rectangle and smaller in size. The lines are discrete and the shapes are formed from discrete lines for an open shape to allow electrical percolation through the openings and retain a substantial amount of the original conductivity of the region.

FIG. 11A is a schematic of a diamond pattern. To render invisible, dashed lines may be patterned within each diamond parallel to the sides of the diamonds. About 50% of the diamonds may be patterned with discrete lines that are parallel to a first pair of parallel sides, and the other portion of the diamonds may be patterned with discrete lines that are parallel to the other pair of parallel sides as shown. FIG. 11B shows a single diamond comprising discrete lines patterned in both directions, parallel to a first pair of parallel sides and a second pair of parallel sides.

### Patterning Methods

Various patterning methods may be employed to create patterns in electrically conductive films, such as chemical etching, irradiation by a radiation source such as a laser or the like. In some embodiments of chemical etching, the process may comprise printing a chemically resistant mask or laminating a photo-resist, exposing it, and developing it. In some embodiments of chemical etching, the process may comprise directly printing an etchant with the desired pattern. Patterning may be accomplished at any point of the assembly process of the electrically conductive film. In some embodiments, patterning may be performed simultaneously with the deposition of the electrically conductive layer. In some embodiments, patterning may be performed after the deposition of the electrically conductive layer. In some cases, patterning may be performed after all the layers of the electrically conductive film are assembled, e.g. hard coat layer, electrically conductive layer, substrate, and top coat layer.

It may be desirable to produce an electrically conductive film comprising a first region exhibiting a first conductivity and a second region exhibiting a second conductivity that is greater than the first conductivity. For the first conductivity to be less than the second conductivity, the first region may be patterned. However, the first pattern may be visible to the unaided human eye, which may not be a desirable effect. The visibility of the first pattern may be corrected by producing a second pattern in the second region. However, it may be desirable to maintain the second conductivity to be higher than the first conductivity. In some embodiments, the second pattern may comprise discrete lines to afford conductivity and render pattern invisibility. In some embodiments, the patterning method may be adjusted to account for differences in conductivity for the first region and the second region. In such cases, the second pattern may comprise either discrete or continuous paths.

In some embodiments, patterns may be formed by irradiating the electrically conductive film with a radiation source. The radiation source may be a laser, such as an ultraviolet (UV) laser or an infrared (IR) laser. The laser may be a pulsed or continuous wave laser. In cases where a pulsed laser is used, the pulse duration of the laser may be on the order of micro-, nano-, pico-, or femtoseconds. The laser may be a solid-state laser, such as a diode-pumped solid state laser, a semiconductor laser, or a fiber laser. In some embodiments, the electrically conductive film is irradiated with a pulsed UV laser, such as a frequency tripled yttrium aluminum garnet (YAG) or yttrium orthovanadate (Nd:YVO4) lasers.

The parameters of the laser may be adjusted to account for differences in conductivity between the first region and the second region. In some embodiments where the second pattern comprises a discrete path, the first region and the second region may be patterned using different laser settings, such that the second region has a higher conductivity than the first region. In some embodiments, the first pattern may be formed in the first region by a laser operating at a first power, and the second pattern may be formed in the second region by the laser operating at a second power, the second power being lower than the first power. In some embodiments involving a pulsed laser, the first pattern may be formed in the first region by the pulsed laser operating at a first power, and the second pattern may be formed in the second region by the pulsed laser operating at a second power, the second power being lower than the first power.

In some embodiments, the first pattern may be formed in the first region by a laser operating at a first scan speed, and the second pattern may be formed in the second region by the laser operating at a second scan speed, the second scan speed being higher than the first scan speed. In some embodiments, the first pattern may be formed in the first region by a laser operating at a first repetition rate, and the second pattern may be formed in the second region by the laser operating at a second repetition rate, the second repetition rate being lower than the first repetition rate. In some embodiments involving a pulsed laser, a lower scan speed or a lower repetition rate of the laser beam may result in less overlap between pulses, resulting in a pattern of a series of dots rather than a continuous line. In some embodiments, the first pattern may be formed in the first region by a laser operating at a first pulse-to-pulse overlap percent, and the second pattern may be formed in the second region by the laser operating at a second pulse-to-pulse overlap percent, the second pulse-to-pulse overlap percent being lower than the first pulse-to-pulse overlap percent.

In some cases involving a pulsed laser, the second pattern in the second region may comprise a continuous line rather than discrete lines. In such cases, there may be higher throughput because the scanning system does not have to stop and start moving minors for each discrete line.

In some embodiments, patterns may be formed by etching the electrically conductive film with an etchant, such as an acid etching solution. The etching method may be adjusted to account for differences in conductivity between the first region and the second region. In some embodiments, the first pattern may be formed by using an acid etching solution with a first concentration of acid, and the second pattern may be formed by using an acid etching solution with a second concentration of acid, the first concentration of acid being higher than the second concentration of acid. In some embodiments, the first region is exposed to the acid etching solution for a first duration, and the second region is exposed to the acid etching solution for a second duration, the first duration being longer than the second duration. In some embodiments, the first region and the second region are exposed to the same acid of the same concentration for the same duration, and the first region and the second region are patterned using the same mask comprising the same pattern. In some embodiments, the first region and the second region are exposed to the same acid of the same concentration for the same duration, but the first region and the second region are patterned using a respective first mask comprising a first pattern and second mask comprising a second pattern. In such cases, the second pattern in the second mask may comprise smaller open areas for etching than the first pattern in the first mask.

### Conductivity

Without wishing to be bound by theory, it is believed that the first region may exhibit a lower conductivity because subjecting nanowires to a patterning process, such as from a pulsed laser, may cause the nanowires to separate into smaller nanostructures, which disrupts the electrical interconnection among nanowires. In some embodiments, the nanostructures may be spaced apart from each other, such that they no longer electrically connect or communicate. When subjected to a patterning process, the ends of the nanowire may separate from the body of the nanowire in a separation process in which the point of attachment between the ends of the nanowire and the body of the nanowire narrows to the point of separation of the ends of the nanowire from the nanowire body. The separation process may continue with the remaining nanowire. For example, the ends of the remaining nanowire may separate from the body of the remaining nanowire in a separation process in which the point of attachment between the ends of the nanowire and the body of the remaining nanowire narrows to the point of separation of the ends of the nanowire from the body of the remaining nanowire. In some embodiments, the nanowires are melted into nanostructures. In some embodiments, the separation process may continue after the electrically conductive film is exposed to radiation. In some embodiments, the surface of the wires may be altered chemically such that conductivity though the network is substantially decreased or they may be etched away entirely.

In some embodiments where the first region exhibits a first conductivity less than the conductivity of the second region, the average length of the plurality of electrical conductors in the first region may be less than the average length of the plurality of electrical conductors in the second region. In some embodiments, the lengths of the plurality of electrical conductors in the second region 34 may be between about 1 to 100 micrometers. In some embodiments, the lengths of the plurality of electrical conductors in the second region 34 may be between about 5 to 30 micrometers. In some embodiments, some of the plurality of electrical conductors in the first region 32 may comprise lengths between about 5 to 30 micrometers, between about 5 to 500 nanometers, between about 1 to 5 micrometers, or between about 1 to 10 micrometers. For example, the first region may comprise silver nanowires having lengths between about 5 to 30 micrometers, silver nanospheres having lengths between about 5 to 500 nanometers, and silver nanorods between about 1 to 10 micrometers or between about 1 to 5 micrometers.

### Optical Properties

After exposing the first region and the second region of the conductive film to a laser beam, the first region may exhibit a first consequent set of optical properties and the second region may exhibit a second consequent set of optical properties, the first consequent set of optical properties being substantially identical to the second consequent set of optical properties. For the purpose of this application, the term “substantially identical” indicates differences that are not discernible to the unaided human eye. For example, the preexisting set of optical properties may differ from the consequent set of optical properties by less than about 10%, less than about 5%, or less than about 1%.

Such a first consequent set of optical properties may, for example, comprise one or more of a first consequent total light transmission, a first consequent haze, a first consequent reflectance value, a first consequent distribution of spectral values, a first consequent L* value, a first consequent a* value, or a first consequent b* value. Such a second consequent set of optical properties may, for example, comprise one or more of a second consequent total light transmission, a second consequent haze, a second consequent reflectance value, a second consequent distribution of spectral values, a second consequent L* value, a second consequent a* value, or a second consequent b* value. For the purpose of this application, “substantially similar optical appearance” indicates that differences in total light transmission, haze, L*, a*, and b* are not discernible to the unaided human eye. The L* value, a* value, and b* value are part of the Commission Internationale de l'Eclairage (CIE) system of describing the color of an object.

### EXEMPLARY EMBODIMENTS

U.S. Provisional Patent Application No. 61/893,387, filed Oct. 21, 2013, entitled “INVISIBLE PATTERNS FOR TRANSPARENT ELECTRICALLY CONDUCTIVE FILMS,” which is hereby incorporated by reference in its entirety, disclosed the following 65 non-limiting exemplary embodiments.

A. A device comprising:

an electrically conductive film comprising a first set of electrically conductive nanostructures in a first region exhibiting a first conductivity and a second set of electrically conductive nanostructures in a second region exhibiting a second conductivity, the second conductivity being greater than the first conductivity,

a first pattern disposed in the first region of the electrically conductive film along a first path having a first shape that exhibits a first spatial frequency distribution, and

a second pattern disposed in the second region of the electrically conductive film along a second path having a second shape that exhibits a second spatial frequency distribution,

wherein the combination of the first pattern in the first region and the second pattern in the second region result in a combined spatial frequency distribution that is invisible to the unaided human eye.

B. The device of embodiment A, wherein the first set of electrically conductive nanostructures has a first average length and the second set of electrically conductive nanostructures has a second average length, the first average length being smaller than the second average length.
C. The device of either of embodiments A or B, wherein the second shape is geometrically similar to the first shape.
D. The device of any of embodiments A-C, wherein the second shape is substantially identical to the first shape.
E. The device of any embodiments A-D, wherein the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.
F. The device of any of embodiments A-E, further comprising a third pattern disposed in the second region of the conductive film.
G. The device of any of embodiments A-F, wherein the first and second shapes comprise straight lines.
H. The device of any of embodiments A-G, wherein the first spatial frequency distribution and the second spatial frequency distribution are two-dimensional.
J. The device of any of embodiments A-H, wherein the first path is a continuous path, and the second path is a discrete path.
K. The device of any of embodiment A-J, wherein the electrically conductive nanostructures comprises silver nanowires.
L. A method comprising:

providing an electrically conductive film comprising a first set of electrically conductive nanostructures in a first region exhibiting a first conductivity and a second set of electrically conductive nanostructures in a second region exhibiting a second conductivity,

forming a visible first pattern in the first region of the electrically conductive film along a first path having a first shape that exhibits a first spatial frequency distribution, and

forming a second pattern in the second region of the electrically conductive film along a second path having a second shape that is geometrically similar to the first shape that forms a second spatial frequency distribution,

wherein, after forming the first pattern in the first region and forming the second pattern in the second region, the first region of the conductive film exhibits a third conductivity that is less than the second conductivity and the combination of the first pattern in the first region and the second pattern in the second region result in a combined spatial frequency distribution that is invisible to the unaided human eye.

M. The method of embodiment L, wherein the first set of electrically conductive nanostructures has a first average length and the second set of electrically conductive nanostructures has a second average length, the first average length being smaller than the second average length.
N. The method of either of embodiments L or M, wherein the first spatial frequency distribution and the second frequency distribution are two-dimensional.
P. The method of any of embodiments L-N, further comprising a third pattern disposed in the second region of the electrically conductive film.
Q. The method of any of embodiments L-P, wherein the first shape and second shape each comprise at least one straight line.
R. The method of any of embodiments L-Q, wherein the first shape and second shape each comprise at least one curved line.
S. The method of any of embodiments L-R, wherein the first path is a continuous path, and the second path is a discrete path.
T. The method of any of embodiments L-S, wherein forming the first pattern in the first region comprises irradiating along a first path with a first radiation source, and wherein forming the second pattern in the second region comprises irradiating along a second path with a second radiation source.
U. The method of any of embodiments L-T, wherein the electrically conductive nanostructures comprise silver nanowires.
V. The method of any of embodiments L-U, wherein forming the first pattern in the first region comprises irradiating along the first path with a first radiation source at a first power, and wherein forming the second pattern in the second region comprises irradiating along the second path with a second radiation source at a second power, the first power being greater than the second power.
W. The method of any of embodiments L-V, wherein forming the first pattern in the first region comprises irradiating along the first path with a first radiation source at a first repetition rate, and wherein forming the second pattern in the second region comprises irradiating along the second path with a second radiation source at a second repetition rate, the first repetition rate being greater than the second repetition rate.
X. The method of any of embodiments L-W, wherein forming the first pattern in the first region comprises irradiating along the first path with a first radiation source at a first scan speed, and wherein forming the second pattern in the second region comprises irradiating along the second path with a second radiation source at a second scan speed, the second scan speed being greater than the second scan speed.
Y. The method of any of embodiments L-X, wherein forming the first pattern in the first region comprises irradiating along the first path with a first radiation source at a first pulse-to-pulse overlap percent, and wherein forming the second pattern in the second region comprises irradiating along the second path with a second radiation source at a second pulse-to-pulse overlap percent, the first pulse-to-pulse overlap percent being greater than the second pulse-to-pulse overlap percent.
Z. The method of any of embodiments T-Y, wherein the first radiation source and the second radiation source are the same.
AA. The method of any of embodiments T-Y, wherein the first radiation source and the second radiation source are different.
AB. The method of any of embodiments L-R, wherein forming the first pattern in the first region comprises exposing the first region of the electrically conductive film along the first path with an etchant, and wherein forming the second pattern in the second region comprises exposing the second region of the electrically conductive film along the second path with the etchant.
AC. The method of any of embodiments L-AB, wherein prior to forming the pattern in the first region and the second pattern in the second region, the first region exhibits a first preexisting set of optical properties and the second region exhibits a second preexisting set of optical properties, and after forming the pattern in the first region and the second pattern in the second region, the first region exhibits a first consequent set of optical properties and the second region exhibits a second consequent set of optical properties, the first consequent set of optical properties and the second consequent set of optical properties being substantially identical.
AD. The method of embodiment AC, wherein the first consequent set of optical properties comprises a first consequent total light transmission and the second consequent set of optical properties comprises a second consequent total light transmission that is substantially identical to the first consequent total light transmission.
AE. The method of either of embodiments AB or AC, wherein the first consequent set of optical properties comprises a first consequent haze and the second consequent set of optical properties comprises a second consequent haze that is substantially identical to the first consequent haze.
AF. The method of any of embodiment AC-AE, wherein the first consequent set of optical properties comprises a first consequent L* value and the second consequent set of optical properties comprises a second consequent L* value that is substantially identical to the first consequent L* value.
AG. The method of any of embodiment AC-AF, wherein the first consequent set of optical properties comprises a first consequent a* value and the second consequent set of optical properties comprises a second consequent a* value that is substantially identical to the first consequent a* value.
AH. The method of any of embodiment AC-AG, wherein the first consequent set of optical properties comprises a first consequent b* value and the second consequent set of optical properties comprises a second consequent b* value that is substantially identical to the first consequent b* value.
AJ. The method of any of embodiment AC-AH, wherein the first consequent set of optical properties comprises a first consequent distribution of spectral values and the second consequent set of optical properties comprises a second consequent distribution of spectral values that is substantially identical to the first consequent distribution of spectral values.
AK. The method of any of embodiment AC-AJ, wherein the first consequent set of optical properties comprises a first consequent reflectance value and the second consequent set of optical properties comprises a second consequent reflectance value that is substantially identical to the first consequent reflectance value.
AL. The method of any of embodiments L-AK, wherein, after forming the second pattern in the second region of the electrically conductive film, the second region exhibits a fourth conductivity, the fourth conductivity and the second conductivity being substantially identical.
AM. The method of any of embodiments L-AL, wherein the magnitude of the first spatial frequency distribution is composed of spatial frequencies substantially identical to the magnitude of the second spatial frequency distribution.
AN. The method of any of embodiments L-AM, wherein the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.
AP. A system comprising:

a first electrically conductive film comprising a first set of electrically conductive nanostructures in a first region exhibiting a first conductivity and second set of electrically conductive nanostructures in a second region exhibiting a second conductivity, the first conductivity being greater than the second conductivity,

a first pattern disposed in the first region of the first electrically conductive film along a first path having a first shape comprising one or more lines that exhibits a first spatial frequency distribution,

a second pattern disposed in the second region of the first electrically conductive film along a second path having a second shape comprising one or more lines that exhibits a second spatial frequency distribution,

wherein the combination of the first pattern in the first region and the second pattern in the second region result in a combined spatial frequency distribution that is invisible to the unaided human eye;

wherein the first electrically conductive film is operable to detect a change in capacitance.

AQ. The system of embodiment AP comprising:

a second conductive film comprising a third set of electrically conductive nanostructures in a third region exhibiting a third conductivity and fourth set of electrically conductive nanostructures in a fourth region exhibiting, the third conductivity being greater than the fourth conductivity,

a third pattern disposed in the third region of the second electrically conductive film along a third path having a third shape that exhibits a third spatial frequency distribution,

a fourth pattern disposed in the fourth region of the second electrically conductive film along a fourth path having a second shape that exhibits a fourth spatial frequency distribution,

wherein the combination of the first pattern in the first region and the second pattern in the second region result in a combined spatial frequency distribution that is invisible to the unaided human eye;

wherein the first electrically conductive film and second electrically conductive film are operable to detect a change in capacitance.

AR. A method comprising:

providing a first electrically conductive film comprising a first set of electrically conductive nanostructures in a first region exhibiting a first conductivity and second set of electrically conductive nanostructures in a second region exhibiting a second conductivity, the first conductivity being greater than the second conductivity, a visible first pattern disposed in the first region of the first electrically conductive film along a first path having a first shape comprising a line that exhibits a first spatial frequency, and

modifying the first pattern to form a modified pattern having a modified spatial frequency distribution that is invisible to the unaided human eye.

AS. The method of embodiment AR, wherein modifying the first pattern comprises adding a second pattern, and wherein the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.
AT. A method comprising:

adding a second pattern that exhibits a second spatial frequency distribution to a transparent electrically conductive film comprising a visible first pattern that exhibits a first spatial frequency distribution, the visible first pattern comprising a first shape that comprises a boundary that defines a body portion and a plurality of projections extending from the body portion, the second pattern comprising a plurality of spaced apart lines disposed in a region within the plurality of projections of the first shape,

wherein the combination of the first pattern and the second pattern result in a combined spatial frequency distribution that is invisible to the unaided human eye.

AU. The method of embodiment AT, wherein the body portion has a longitudinal dimension, and each of the plurality of projections are substantially perpendicular to the longitudinal dimension of the body portion.
AV. The method of either of embodiments AT or AU, wherein the each of the plurality of spaced apart lines of the second pattern are substantially parallel to the longitudinal dimension of the body portion.
AW. The method of any of embodiments AT-AV, wherein areas near the boundary of the first pattern exhibits a first conductivity and the region comprising the second pattern exhibits a second conductivity, the second conductivity being greater than the first conductivity.
AX. The method of any of embodiments AT-AW, wherein the first shape has a maximum contrast at a first spatial frequency, and wherein the first shape of the first pattern is disposed in a first position and the second shape of the second pattern is disposed in a second position that is about 180 degrees out of phase with the first position at the first spatial frequency.
AY. A method comprising:

adding a second pattern that exhibits a second spatial frequency distribution to a transparent electrically conductive film comprising a visible first pattern comprising a first shape having a boundary that exhibits a first spatial frequency distribution, the second pattern comprising a plurality of spaced apart shapes disposed in a region near the visible first pattern,

wherein the combination of the first pattern and the second pattern result in a combined spatial frequency distribution that is invisible to the unaided human eye.

AZ. The method of embodiment AY, wherein the plurality of spaced apart shapes comprises a plurality of spaced apart lines.
BA. The method of either of embodiments AY or AZ, wherein the visible first pattern comprises a first shape, the first shape having a boundary defining a body portion having a longitudinal dimension and a plurality of projections extending substantially perpendicular from the longitudinal dimension of the body portion.
BB. The method of any of embodiments AY-BA, wherein each of the plurality of spaced apart shapes of the second pattern are substantially parallel to the longitudinal dimension of the body portion.
BC. The method of any of embodiments AY-BB, wherein areas near the boundary of the first pattern exhibits a first conductivity and the region comprising the second pattern exhibits a second conductivity, the second conductivity being greater than the first conductivity.
BD. The method of any of embodiments AY-BC, wherein the first shape has a maximum contrast at a first spatial frequency, and wherein the first shape of the first pattern is disposed in a first position and the second shape of the second pattern is disposed in a second position that is about 180 degrees out of phase with the first position at the first spatial frequency.
BE. A method comprising:

adding a second pattern that exhibits a second spatial frequency distribution to a second region of a transparent electrically conductive film comprising a visible first pattern that exhibits a first spatial frequency distribution,

wherein the combination of the first pattern and the second pattern result in a combined spatial frequency distribution that is invisible to the unaided human eye.

BF. The method of embodiment BE, wherein the first pattern comprises a first shape, the first shape having a boundary defining a body portion having a longitudinal dimension and a plurality of projections extending substantially perpendicular from the longitudinal dimension of the body portion, and wherein the second pattern is disposed within the first shape.
BG. The method of either of embodiments BE or BF, wherein the second pattern comprises a plurality of spaced apart shapes disposed in a region near the first pattern.
BH. The method of any of embodiments BE-BG, wherein the second pattern comprises a plurality of spaced apart rectangles disposed in a region near the first pattern.
BJ. The method of either of embodiments BF or BG, wherein the second pattern is disposed in a region within the first pattern.
BK. The method of any of embodiments BG-BJ, wherein each of the plurality of spaced apart shapes of the second pattern are disposed substantially parallel to the longitudinal dimension of the body portion.
BL. The method of any of embodiments BE-BK, wherein the first pattern is disposed in a first region of the transparent electrically conductive film that exhibits a first conductivity and the second pattern is disposed in a second region of the transparent electrically conductive film that exhibits a second conductivity, wherein the second conductivity is greater than the first conductivity.
BM. The method of any of embodiments BG-BJ, wherein areas near the boundary of the first pattern exhibits a first conductivity and the region comprising the second pattern exhibits a second conductivity, the second conductivity being greater than the first conductivity.
BN. The method of any of embodiments BE-BM, wherein the first shape has a maximum contrast at a first spatial frequency, and wherein the first shape of the first pattern is disposed in a first position and the second shape of the second pattern is disposed in a second position that is about 180 degrees out of phase with the first position at the first spatial frequency.
BP. The method of any of embodiments BE-BN, wherein the second pattern is added by irradiating the transparent electrically conductive film with a UV pulsed laser.
BQ. The method of embodiment BE, wherein the first pattern comprises a first shape, the first shape having a boundary defining a body portion having a longitudinal dimension and a plurality of projections extending substantially perpendicular from the longitudinal dimension of the body portion, and wherein the second pattern is disposed within the first shape substantially perpendicular to the longitudinal dimension of the body portion.
BR. The method of embodiment BE, wherein the first pattern comprises a first shape, the first shape having a boundary defining a body portion having a longitudinal dimension and a plurality of projections extending substantially perpendicular from the longitudinal dimension of the body portion, and wherein the second pattern is disposed within the first shape substantially parallel to the longitudinal dimension of the body portion.
BS. The method of any of embodiments BE-BP,

wherein the first pattern comprises a first shape, the first shape having a boundary defining a body portion having a longitudinal dimension, a plurality of projections extending substantially perpendicular from the longitudinal dimension of the body portion at a first side of the body portion, and a plurality of lines extending from a second side of the body portion opposite the first side and a portion of which extends parallel to the longitudinal dimension of the body portion,

further comprising a visible third pattern disposed near the first pattern and comprises a third shape, the third shape having a boundary defining a body portion having a longitudinal dimension, a plurality of projections extending substantially perpendicular from the longitudinal dimension of the body portion at a first side of the body portion, and a plurality of lines extending from a second side of the body portion opposite the first side and a portion of which extends parallel to the longitudinal dimension of the body portion, the plurality of projections of the third shape being aligned with the plurality of projections of the third shape, the plurality of lines of the third shape being substantially parallel with the plurality of lines of the first shape,

further comprising a fourth pattern comprising a plurality of spaced apart lines disposed within the first shape substantially parallel with the longitudinal dimension of the body portion of the first shape, and

wherein the second pattern is disposed within the first shape substantially parallel with the longitudinal dimension of the body portion of the first shape.

### EXAMPLES

### Example 1

### Prophetic

A sample of transparent conductive film comprising a silver nanowire containing layer on a polyethylene terephthalate (PET) substrate between an overcoat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a first pattern is created in a first region, and the second region remains unpatterned. The first pattern comprises at least one continuous path, for example, a continuous straight line or continuous curved line or continuous geometric shape. When such a continuous path of lines forms shapes, these shapes are closed shapes.

Electrical resistance, transmission, reflection, haze, L*, a*, b*, spectral value, and reflectance are measured and calculated for the raw film and first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total pattern visibility value. As an example, when the pattern has high contrast in the medium frequency range where the contrast sensitivity is high, the visibility value for that pattern will be higher than a pattern that has low contrast in the medium frequency range and high contrast in the high frequency range where the contrast sensitivity is lower.

### Example 2

### Prophetic

A sample of transparent conductive film comprising a silver nanowire containing layer on a polyethylene terephthalate (PET) substrate between an overcoat layer and a hard coat layer is prepared. The sample of the transparent conductive film is irradiated by a suitable type of UV laser of suitable pulse repetition rate, pulse time duration, laser peak output power, single pulse energy, pulse peak power, focused spot size, and scan speed. The laser is operated at a suitable attenuated peak power (i.e. suitable percent laser power). Under these laser conditions, a first pattern is created in a first region and a second pattern is created in a second region. The first pattern comprises at least one continuous path, for example, a continuous straight line or continuous curved line or geometric shape. When such continuous path of lines forms shapes, these shapes are closed shapes. The second pattern comprises at least one discrete path comprising, for example, discrete straight lines or discrete curved lines or geometric shape comprising discrete lines. The design of the second pattern is geometrically similar to the design of the first pattern.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total pattern visibility value.

### Example 3

### Prophetic

A sample of transparent conductive film comprising a silver nanowire containing layer on a polyethylene terephthalate (PET) substrate between an overcoat layer and a hard coat layer is prepared. The sample of the transparent conductive film is irradiated by a suitable type of UV laser. A first pattern is created in a first region using a first laser power and a second pattern is created in a second region using a second laser power, the first laser power being greater than the second laser power. The first pattern comprises at least one continuous path, for example, a continuous straight line or continuous curved line or geometric shapes. The second pattern comprises at least one continuous path comprising, for example, continuous straight lines or continuous curved lines or geometric shapes. The second pattern and the first pattern are substantially identical spatial frequencies.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 4

### Prophetic

A sample of transparent conductive film comprising a silver nanowire containing layer on a polyethylene terephthalate (PET) substrate between an overcoat layer and a hard coat layer is prepared. The sample of the transparent conductive film is irradiated by a suitable type of UV laser. A first pattern is created in a first region using a first laser power and a second pattern is created in a second region using a second laser power, the first laser power being greater than the second laser power. The first pattern comprises at least one continuous path, for example, a continuous straight line or continuous curved line or geometric shapes. The second pattern comprises at least one discrete path comprising, for example, discrete straight lines or discrete curved lines or geometric shapes comprising discrete lines. The second pattern and the first pattern are substantially identical.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 5

### Prophetic

A sample of transparent conductive film comprising a silver nanowire containing layer on a polyethylene terephthalate (PET) substrate between an overcoat layer and a hard coat layer is prepared. Using an acid etchant, such as ferric chloride, a first pattern is created in a first region. The second region remains unpatterned. The first pattern comprises at least one continuous path, for example, a continuous straight line or continuous curved line or continuous geometric shape. When such continuous path of lines forms shapes, these shapes are closed shapes.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 6

### Prophetic

A sample of transparent conductive film comprising a silver nanowire containing layer on a polyethylene terephthalate (PET) substrate between an overcoat layer and a hard coat layer is prepared. Using an acid etchant, such as ferric chloride, a first pattern is created in a first region and a second pattern is created in a second region. The first pattern comprises at least one continuous path, for example, a continuous straight line or continuous curved line or geometric shape. When such continuous path of lines forms shapes, these shapes are closed shapes. The second pattern comprises at least one discrete path comprising, for example, discrete straight lines or discrete curved lines or geometric shape comprising discrete lines. The design of the second pattern is geometrically similar to the design of the first pattern.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 7

### Prophetic

A sample of transparent conductive film comprising a silver nanowire containing layer on a polyethylene terephthalate (PET) substrate between an overcoat layer and a hard coat layer is prepared. The sample of the transparent conductive film is etched by an etching solution. A first pattern is created in a first region using a first acid concentration and a second pattern is created in a second region using a second acid concentration, the first acid concentration being greater than the second acid concentration. The duration of acid exposure is the same for the first pattern and the second pattern. The first pattern comprises at least one continuous path, for example, a continuous straight line or continuous curved line or geometric shapes. The second pattern comprises at least one continuous path comprising, for example, continuous straight lines or continuous curved lines or geometric shapes. The second pattern and the first pattern are substantially identical.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 8

### Prophetic

A sample of transparent conductive film comprising a silver nanowire containing layer on a polyethylene terephthalate (PET) substrate between an overcoat layer and a hard coat layer is prepared. The sample of the transparent conductive film is etched using an acid etching solution. A first pattern is created in a first region using a first acid concentration and a second pattern is created in a second region using a second acid concentration, the first acid concentration being greater than the second acid concentration. The duration of acid exposure is the same for the first pattern and the second pattern. The first pattern comprises at least one continuous path, for example, a continuous straight line or continuous curved line or geometric shapes. The second pattern comprises at least one discrete path comprising, for example, discrete straight lines or discrete curved lines or geometric shapes comprising discrete lines. The second pattern and the first pattern are substantially identical.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 9

### Prophetic

A sample of transparent conductive film comprising a silver nanowire containing layer on a polyethylene terephthalate (PET) substrate between an overcoat layer and a hard coat layer is prepared. The sample of the transparent conductive film is etched by an etching solution. A first pattern is created in a first region by exposure to an etchant for a first duration and a second pattern is created in a second region by exposure to an etchant for a second duration, the first duration being longer than the second duration. The etchant is the same for the first pattern and the second pattern. The first pattern comprises at least one continuous path, for example, a continuous straight line or continuous curved line or geometric shapes. The second pattern comprises at least one continuous path comprising, for example, continuous straight lines or continuous curved lines or geometric shapes. The second pattern and the first pattern are substantially identical.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

### Example 10

### Prophetic

A sample of transparent conductive film comprising a silver nanowire containing layer on a polyethylene terephthalate (PET) substrate between an overcoat layer and a hard coat layer is prepared. The sample of the transparent conductive film is etched using an acid etching solution. A first pattern is created in a first region by exposure to an etchant for a first duration and a second pattern is created in a second region by exposure to an etchant for a second duration, the first duration being longer than the second duration. The etchant is the same for the first pattern and the second pattern. The first pattern comprises at least one continuous path, for example, a continuous straight line or continuous curved line or geometric shapes. The second pattern comprises at least one discrete path comprising, for example, discrete straight lines or discrete curved lines or geometric shapes comprising discrete lines. The second pattern and the first pattern are substantially identical.

Electrical resistance, transmission, reflection, haze, L*, a*, b*, spectral value, and reflectance are measured and calculated for the first and second regions. The sample may be analyzed for effects on the nanowires and surrounding polymer. The sample is imaged with a reflective scanner or a camera, such as a CMOS or CCD camera, under reflective light to visualize the contrast in the two regions over a large area. The scanned image is calibrated for pixels per microns. The scanner or camera is calibrated for pixel value versus brightness. A 2D Fast Fourier Transform (FFT), Fourier Transform or functional equivalent, such as a wavelet transform, is performed, and the resulting contrast as a function of spatial frequency is multiplied at each frequency with the contrast sensitivity of the unaided human eye in the same spatial frequency units. The curve is integrated to yield a total visibility value.

What is claimed:

1. A device comprising:
an electrically conductive film comprising a first set of electrically conductive nanostructures in a first region exhibiting a first conductivity and a second set of electrically conductive nanostructures in a second region exhibiting a second conductivity, the second conductivity being greater than the first conductivity,
a first pattern disposed in the first region of the electrically conductive film along a first path having a first shape that exhibits a first spatial frequency distribution, and
a second pattern disposed in the second region of the electrically conductive film along a second path having a second shape that exhibits a second spatial frequency distribution,
wherein the combination of the first pattern in the first region and the second pattern in the second region results in a combined spatial frequency distribution that is invisible to the unaided human eye.

2. The device according to claim 1, wherein the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.

3. The device according to claim 1, further comprising a third pattern disposed in the second region of the conductive film.

4. The device according to claim 1, wherein the first path is a continuous path, and the second path is a discrete path.

5. The device according to claim 1, wherein the second shape is geometrically similar to the first shape.

6. The device according to claim 1, wherein the first and second sets of electrically conductive nanostructures comprise silver nanowires.

7. The device according to claim 1, wherein the first electrical film is configured to detect a change in capacitance.

8. The device according to claim 1, further comprising:
a second conductive film comprising a third set of electrically conductive nanostructures in a third region exhibiting a third conductivity and a fourth set of electrically conductive nanostructures in a fourth region exhibiting a fourth conductivity, the third conductivity being greater than the fourth conductivity,
a third pattern disposed in the third region of the second conductive film along a third path having a third shape that exhibits a third spatial frequency distribution,
a fourth pattern disposed in the fourth region of the second electrically conductive film along a fourth path having a second shape that exhibits a fourth spatial frequency distribution,
wherein the combination of the third pattern in the third region and the fourth pattern in the fourth region result in a combined spatial frequency distribution that is invisible to the unaided human eye.

9. The device according to claim 8, wherein the first electrically conductive film and second electrically conductive film are configured to detect a change in capacitance.

10. The device according to claim 8, wherein the third set of electrically conductive nanostructures and the fourth set of electrically conductive nanostructures comprise silver nanowires.

11. A method comprising:
providing an electrically conductive film comprising a first set of electrically conductive nanostructures in a first region exhibiting a first conductivity and a second set of electrically conductive nanostructures in a second region exhibiting a second conductivity,
forming a visible first pattern in the first region of the electrically conductive film along a first path having a first shape that exhibits a first spatial frequency distribution, and
forming a second pattern in the second region of the electrically conductive film along a second path having a second shape that exhibits a second spatial frequency distribution,
wherein, after forming the first pattern in the first region and forming the second pattern in the second region, the first region of the conductive film exhibits a third conductivity that is less than the second conductivity, and the combination of the first pattern in the first region and the second pattern in the second region result in a combined spatial frequency distribution that is invisible to the unaided human eye.

12. The method according to claim 11, wherein the first path is a continuous path and the second path is a discrete path.

13. The method according to claim 11, wherein the first shape has a maximum contrast at a first spatial frequency, and wherein the first shape of the first pattern is disposed in a first position in the first region of the electrically conductive film and the second shape of the second pattern is disposed in a second position in the second region of the electrically conductive film that is about 180 degrees out of phase with the first position at the first spatial frequency.

14. The method according to claim 11, wherein the second shape is geometrically similar to the first shape.

15. The method according to claim 11, where the first and second sets of conductive nanostructures comprise silver nanowires.

16. The method according to claim 11, wherein the first set of electrically conductive nanostructures has a first average length and the second set of electrically conductive nanostructures has a second average length, the first average length being smaller than the second average length.
